(19) United States
(12) Patent Application Publication
(10) Pub. No.: US 2024/0312756 A1
(43) Pub. Date: Sep. 19, 2024

(54) PLATFORM FOR CHARGED PARTICLE APPARATUS AND COMPONENTS WITHIN A CHARGED PARTICLE APPARATUS

(71) Applicant: ASML Netherlands B.V., Veldhoven (NL)

(72) Inventors: Jasper Hendrik GRASMAN, Waalre (NL); Niels Johannes Maria BOSCH, Eindhoven (NL); Patrick Peter Hubert Helena PHILIPS, Geldrop (NL); Peter Paul HEMPENIUS, Eindhoven (NL); Joan SANS MERCADER, Eindhoven (NL); Gerardus Wilhelmus SARS, Riethoven (NL); Hans BUTLER, Best (NL); Willem Henk URBANUS, Culemborg (NL)

(73) Assignee: ASML Netherlands B.V., Veldhoven (NL)

(21) Appl. No.: 18/674,282

(22) Filed: May 24, 2024

Related U.S. Application Data
(63) Continuation of application No. PCT/EP2022/079595, filed on Oct. 24, 2022.
(60) Provisional application No. 63/283,970, filed on Nov. 29, 2021.

(51) Int. Cl. H01J 37/20

(52) U.S. Cl. CPC H01J 37/20; H01J 2237/20235

(57) ABSTRACT

Disclosed herein is a platform for a charged particle apparatus, the platform comprising: a base frame; a chamber arranged to comprise a substrate; a metrology frame arranged to support a charged particle beam generator for irradiating a substrate in the chamber with a charged particle beam; and a bellow arranged between the metrology frame and the chamber; wherein: the chamber is rigidly connected to the base frame; the bellow comprises a flexible material such that the metrology frame is substantially isolated from any vibrations that are generated in the chamber; and the bellow is air tight so that a substantial vacuum may be established in the chamber.

### CROSS-REFERENCE TO RELATED APPLICATIONS

This application claims priority of International application PCT/EP2022/079595, filed on Oct. 24, 2022, which claims priority of U.S. application No. 63/283,970, filed on Nov. 29, 2021. These applications are incorporated herein by reference in their entireties.

### FIELD

The embodiments provided herein generally relate to a platform for supporting a charged particle apparatus as well as components within a charged particle apparatus. Embodiments provide a new platform for supporting either a single beam charged particle apparatus or a multi-beam charged particle apparatus. Embodiments also provide a new long stroke arrangement for moving a stage in a charged particle apparatus. Embodiments also provide new arrangements for reducing detrimental vibration effects.

### BACKGROUND

When manufacturing semiconductor integrated circuit (IC) chips, undesired pattern defects, as a consequence of, for example, optical effects and incidental particles, inevitably occur on a substrate (i.e. wafer) or a mask during the fabrication processes, thereby reducing the yield. Monitoring the extent of the undesired pattern defects is therefore an important process in the manufacture of IC chips. More generally, the inspection and/or measurement of a surface of a substrate, or other object/material, is an important process during and/or after its manufacture.

Pattern inspection tools with a charged particle beam have been used to inspect objects, for example to detect pattern defects. These tools typically use electron microscopy techniques, such as a scanning electron microscope (SEM). In a SEM, a primary electron beam of electrons at a relatively high energy is targeted with a final deceleration step in order to land on a sample at a relatively low landing energy. The beam of electrons is focused as a probing spot on the sample. The interactions between the material structure at the probing spot and the landing electrons from the beam of electrons cause electrons to be emitted from the surface, such as secondary electrons, backscattered electrons, or Auger electrons. The generated secondary electrons may be emitted from the material structure of the sample. By scanning the primary electron beam as the probing spot over the sample surface, secondary electrons can be emitted across the surface of the sample. By collecting these emitted secondary electrons from the sample surface, a pattern inspection tool may obtain an image representing characteristics of the material structure of the surface of the sample.

Another application for a charged particle beam is lithography. The charged particle beam reacts with a resist layer on the surface of a substrate. A desired pattern in the resist can be created by controlling the locations on the resist layer that the charged particle beam is directed towards.

A charged particle apparatus may be an apparatus for generating, illuminating, projecting and/or detecting one or more beams of charged particles. There is a general need to improve on known techniques for providing a charged particle apparatus.

### SUMMARY

A single beam charged particle apparatus generates, illuminates, projects and/or detects a single beam of charged particles. The known platform for supporting a single beam charged particle apparatus has a relatively simple design. A multi-beam charged particle apparatus generates, illuminates, projects and/or detects a plurality of beams of charged particles. The known platform for multi-beam charged particle apparatuses has a complicated design, has a larger footprint than for a single beam platform and is substantially more expensive than a single beam platform. This is necessary to meet the higher performance requirements of multi-beam charged particle apparatuses. There is general need to provide a new platform for a charged particle apparatus that is suitable for either a single beam charged particle apparatus or a multi-beam charged particle apparatus. Relative to the known multi-beam platform, the new platform may have one or more of a simpler design, lower footprint and be less expensive. More generally, there is a need to improve the provision of charged particle apparatuses.

Embodiments provide a number of improvements to the provision of a charged particle apparatus.

According to some embodiments of the present disclosure, there is provided a platform for a charged particle apparatus, the platform comprising: a base frame; a chamber arranged to comprise a substrate; a metrology frame arranged to support a charged particle beam generator for irradiating a substrate in the chamber with a charged particle beam; and a bellow arranged between the metrology frame and the chamber; wherein: the chamber is rigidly connected to the base frame; the bellow comprises a flexible material such that the metrology frame is substantially isolated from any vibrations that are generated in the chamber; and the bellow is air tight so that a substantial vacuum may be established in the chamber.

According to some embodiments of the present disclosure, there is provided a charged particle apparatus comprising: the platform described above; and a charged particle beam generator.

According to some embodiments of the present disclosure, there is provided a bellow for proving a connection between a vacuum chamber and a metrology frame in a platform for a charged particle apparatus, the bellow comprising: a layer of material arranged in a loop; wherein: the material is flexible and substantially air tight; the layer comprises a first end for securing to the chamber; and the layer comprises a second end for securing to the metrology frame.

According to some embodiments of the present disclosure, there is provided a platform for a charged particle apparatus comprising: a chamber; a metrology frame; and the bellow described above; wherein: an inner side of the bellow is arranged to support a substantial vacuum in the chamber; and an outer side of the bellow is arranged to withstand the ambient pressure around the platform.

According to some embodiments of the present disclosure, there is provided a charged particle apparatus comprising: the platform described above, wherein the platform comprises the bellow described above; and a charged particle beam generator.

Other advantages of the present invention will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an exemplary charged particle beam inspection apparatus.

FIG. 2 is a schematic diagram illustrating an exemplary multi-beam apparatus that is part of the exemplary charged particle beam inspection apparatus of FIG. 1.

FIG. 3 is a schematic diagram of exemplary multi-beam apparatus illustrating an exemplary configuration of source conversion unit of the exemplary charged particle beam inspection apparatus of FIG. 1.

FIG. 4 schematically shows a platform for supporting a known single beam charged particle apparatus.

FIG. 5 schematically shows a platform for supporting a known multi-beam charged particle apparatus.

FIG. 6 schematically shows a platform for supporting a charged particle apparatus according to some embodiments of the present disclosure.

FIG. 7 schematically shows a cross-section through a first implementation of a bellow according to some embodiments of the present disclosure.

FIG. 8 schematically shows a cross-section through a second implementation of a bellow according to some embodiments of the present disclosure.

FIGS. 9A and 9B schematically show cross-sections through a third implementation of a bellow according to some embodiments of the present disclosure.

FIG. 10 schematically shows a plan view of an example first implementation of a substrate support movement apparatus according to some embodiments of the present disclosure.

FIG. 11 is a schematic side on view of the example first implementation when provided in a charged particle apparatus.

FIG. 12 is a schematic side view of the substrate support movement apparatus according to some embodiments of the present disclosure.

FIG. 13 schematically shows a known implementation of balance masses in a multi-beam charged particle apparatus.

FIG. 14 schematically shows a balance mass arrangement according to some embodiments of the present disclosure.

FIG. 15 schematically shows an example implementation of a frame of a charged particle apparatus according to some embodiments of the present disclosure.

FIG. 16A shows an example implementation according to some embodiments of the present disclosure;

FIG. 16B shows an example implementation according to some embodiments of the present disclosure.

FIG. 17 shows the magnitude of vibrations caused by the main resonant frequency of the base frame under different damping conditions.

### DESCRIPTION OF EMBODIMENTS

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims.

The reduction of the physical size of devices, and enhancement of the computing power of electronic devices may be accomplished by significantly increasing the packing density of circuit components such as transistors, capacitors, diodes, etc. on an IC chip. This has been enabled by increased resolution enabling yet smaller structures to be made. For example, an IC chip of a smart phone, which is the size of a thumbnail and available in, or earlier than, 2019, may include over 2 billion transistors, the size of each transistor being less than 1/1000th of a human hair. Thus, it is not surprising that semiconductor IC manufacturing is a complex and time-consuming process, with hundreds of individual steps. Errors in even one step have the potential to dramatically affect the functioning of the final product. Just one “killer defect” may cause device failure. The goal of the manufacturing process is to improve the overall yield of the process. For example, to obtain a 75% yield for a 50-step process (where a step may indicate the number of layers formed on a wafer), each individual step must have a yield greater than 99.4%. If an individual step has a yield of 95%, the overall process yield would be as low as 7-8%.

While high process yield is desirable in an IC chip manufacturing facility, maintaining a high substrate (i.e. wafer) throughput, defined as the number of substrates processed per hour, is also essential. High process yield and high substrate throughput may be impacted by the presence of a defect. This is especially if operator intervention is required for reviewing the defects. Thus, high throughput detection and identification of micro and nano-scale defects by inspection tools (such as a Scanning Electron Microscope (‘SEM’)) is essential for maintaining high yield and low cost.

A SEM comprises a scanning device and a detector apparatus. The scanning device comprises an illumination apparatus that comprises an electron source, for generating primary electrons, and a projection apparatus for scanning a sample, such as a substrate, with one or more focused beams of primary electrons. The primary electrons interact with the sample and generate interaction products, such as secondary electrons and/or backscattered electrons. The detection apparatus captures the secondary electrons and/or backscattered electrons from the sample as the sample is scanned so that the SEM may create an image of the scanned area of the sample. For high throughput inspection, some of the inspection apparatuses use multiple focused beams, i.e. a multi-beam, of primary electrons. The component beams of the multi-beam may be referred to as sub-beams or beamlets. A multi-beam may scan different parts of a sample simultaneously. A multi-beam inspection apparatus may therefore inspect a sample at a much higher speed than a single-beam inspection apparatus.

In a multi-beam inspection apparatus, the paths of some of the primary electron beams are displaced away from the central axis, i.e. a mid-point of the primary electron-optical axis (also referred to herein as the charged particle axis), of the scanning device. To ensure all the electron beams arrive at the sample surface with substantially the same angle of incidence, sub-beam paths with a greater radial distance from the central axis need to be manipulated to move through a greater angle than the sub-beam paths with paths closer to the central axis. This stronger manipulation may cause aberrations that cause the resulting image to be blurry and out-of-focus. An example is spherical aberrations which bring the focus of each sub-beam path into a different focal plane. In particular, for sub-beam paths that are not on the central axis, the change in focal plane in the sub-beams is greater with the radial displacement from the central axis. Such aberrations and de-focus effects may remain associated with the secondary electrons from the target when they are detected, for example the shape and size of the spot formed by the sub-beam on the target will be affected. Such aberrations therefore degrade the quality of resulting images that are created during inspection.

An implementation of a known multi-beam inspection apparatus is described below.

The figures are schematic. Relative dimensions of components in drawings are therefore exaggerated for clarity. Within the following description of drawings the same or like reference numbers refer to the same or like components or entities, and only the differences with respect to the individual embodiments are described. While the description and drawings are directed to an electron-optical apparatus, it is appreciated that the embodiments are not used to limit the present disclosure to specific charged particles. References to electrons throughout the present document may therefore be more generally be considered to be references to charged particles, with the charged particles not necessarily being electrons.

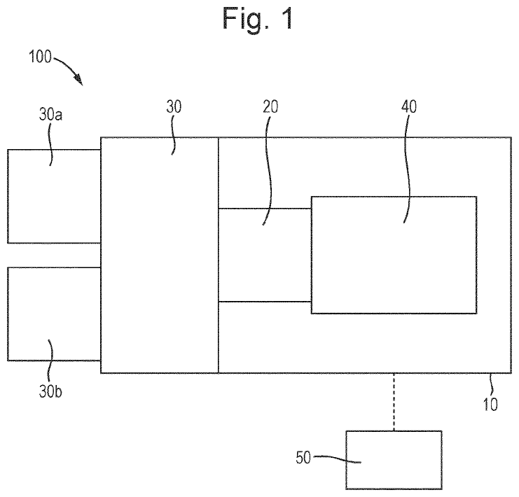

Reference is now made to FIG. 1, which is a schematic diagram illustrating an exemplary charged particle beam inspection apparatus 100. The charged particle beam inspection apparatus 100 of FIG. 1 includes a main chamber 10, a load lock chamber 20, an electron beam tool 40, an equipment front end module (EFEM) 30 and a controller 50.

EFEM 30 includes a first loading port 30a and a second loading port 30b. EFEM 30 may include additional loading port(s). First loading port 30a and second loading port 30b may, for example, receive substrate front opening unified pods (FOUPs) that contain substrates (e.g., semiconductor substrates or substrates made of other material(s)) or samples to be inspected (substrates, wafers and samples are collectively referred to as “samples” hereafter). One or more robot arms (not shown) in EFEM 30 transport the samples to load lock chamber 20.

Load lock chamber 20 is used to remove the gas around a sample. This creates a vacuum that is a local gas pressure lower than the pressure in the surrounding environment. The load lock chamber 20 may be connected to a load lock vacuum pump system (not shown), which removes gas particles in the load lock chamber 20. The operation of the load lock vacuum pump system enables the load lock chamber to reach a first pressure below the atmospheric pressure. After reaching the first pressure, one or more robot arms (not shown) transport the sample from load lock chamber 20 to main chamber 10. Main chamber 10 is connected to a main chamber vacuum pump system (not shown). The main chamber vacuum pump system removes gas molecules in main chamber 10 so that the pressure around the sample reaches a second pressure lower than the first pressure. After reaching the second pressure, the sample is transported to the electron beam tool by which it may be inspected. An electron beam tool 40 may comprise either a single beam or a multi-beam electron-optical apparatus.

Controller 50 is electronically connected to electron beam tool 40. Controller 50 may be a processor (such as a computer) configured to control the charged particle beam inspection apparatus 100. Controller 50 may also include a processing circuitry configured to execute various signal and image processing functions. While controller 50 is shown in FIG. 1 as being outside of the structure that includes main chamber 10, load lock chamber 20, and EFEM 30, it is appreciated that controller 50 may be part of the structure. The controller 50 may be located in one of the component elements of the charged particle beam inspection apparatus or it may be distributed over at least two of the component elements. While the present disclosure provides examples of main chamber 10 housing an electron beam inspection tool, it should be noted that aspects of the disclosure in their broadest sense are not limited to a chamber housing an electron beam inspection tool. Rather, it is appreciated that the foregoing principles may also be applied to other tools and other arrangements of apparatus, that operate under the second pressure.

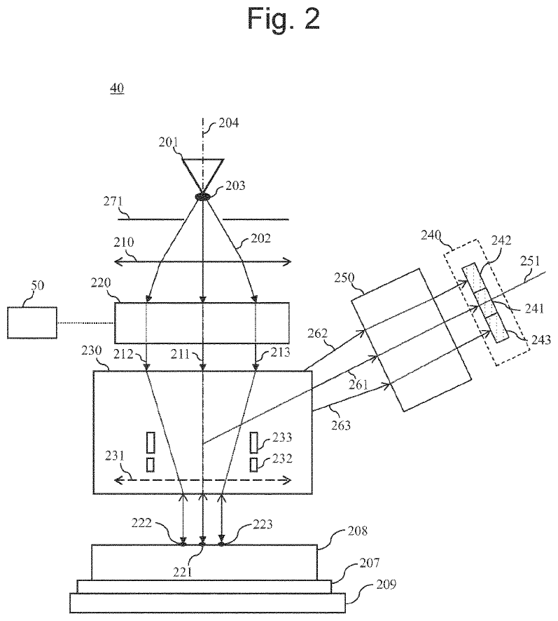

Reference is now made to FIG. 2, which is a schematic diagram illustrating an exemplary electron beam tool 40 including a multi-beam inspection tool that is part of the exemplary charged particle beam inspection apparatus 100 of FIG. 1. Multi-beam electron beam tool 40 (also referred to herein as apparatus 40) comprises an electron source 201, a gun aperture plate 271, a condenser lens 210, a source conversion unit 220, a primary projection apparatus 230, a motorized stage 209, and a sample holder 207. The electron source 201, a gun aperture plate 271, a condenser lens 210, a source conversion unit 220 are the components of an illumination apparatus comprised by the multi-beam electron beam tool 40. The sample holder 207 is supported by motorized stage 209 so as to hold a sample 208 (e.g., a substrate or a mask) for inspection. Multi-beam electron beam tool 40 may further comprise a secondary projection apparatus 250 and an associated electron detection device 240. Primary projection apparatus 230 may comprise an objective lens 231. Electron detection device 240 may comprise a plurality of detection elements 241, 242, and 243. A beam separator 233 and a deflection scanning unit 232 may be positioned inside primary projection apparatus 230.

The components that are used to generate a primary beam may be aligned with a primary electron-optical axis of the apparatus 40. These components may include: the electron source 201, gun aperture plate 271, condenser lens 210, source conversion unit 220, beam separator 233, deflection scanning unit 232, and primary projection apparatus 230. Secondary projection apparatus 250 and its associated electron detection device 240 may be aligned with a secondary electron-optical axis 251 of apparatus 40.

The primary electron-optical axis 204 is comprised by the electron-optical axis of the of the part of electron beam tool 40 that is the illumination apparatus. The secondary electron-optical axis 251 is the electron-optical axis of the of the part of electron beam tool 40 that is a detection apparatus. The primary electron-optical axis 204 may also be referred to herein as the primary optical axis (to aid case of reference) or charged particle optical axis. The secondary electron-optical axis 251 may also be referred to herein as the secondary optical axis or the secondary charged particle optical axis.

Electron source 201 may comprise a cathode (not shown) and an extractor or anode (not shown). During operation, electron source 201 is configured to emit electrons as primary electrons from the cathode. The primary electrons are extracted or accelerated by the extractor and/or the anode to form a primary electron beam 202 that forms a primary beam crossover (virtual or real) 203. Primary electron beam 202 may be visualized as being emitted from primary beam crossover 203.

The formed primary electron beam 202 may be a single beam and a multi-beam may be generated from the single beam. At different locations along the beam path, the primary electron beam 202 may therefore be either a single beam or a multi-beam. By the time it reaches the sample, and preferably before it reaches the projection apparatus, the primary electron beam 202 is a multi-beam. Such a multi-beam may be generated from the primary electron beam in a number of different ways. For example, the multi-beam may be generated by a multi-beam array located before the crossover 203, a multi-beam array located in the source conversion unit 220, or a multi-beam array located at any point in between these locations. A multi-beam array may comprise a plurality of electron beam manipulating elements arranged in an array across the beam path. Each manipulating element may influence at least part of the primary electron beam to generate a sub-beam. Thus the multi-beam array interacts with an incident primary beam path to generate a multi-beam path down-beam of the multi-beam array. The interaction of the multi-beam array with the primary beam may include one or more aperture arrays, individual deflectors e.g. per sub-beam, lenses, stigmators and (aberration) correctors, again e.g. per sub-beam.

Gun aperture plate 271, in operation, is configured to block off peripheral electrons of primary electron beam 202 to reduce Coulomb effect. The Coulomb effect may enlarge the size of each of probe spots 221, 222, and 223 of primary sub-beams 211, 212, 213, and therefore deteriorate inspection resolution. A gun aperture plate 271 may also include multiple openings for generating primary sub-beams (not shown) even before the source conversion unit 220 and may be referred to as a coulomb aperture array.

Condenser lens 210 is configured to focus (or collimate) primary electron beam 202. In some embodiments, the condenser lens 210 may be designed to focus (or collimate) primary electron beam 202 to become a substantially parallel beam and be substantially normally incident onto source conversion unit 220. Condenser lens 210 may be a movable condenser lens that may be configured so that the position of its principle plane is movable. In some embodiments, the movable condenser lens may be configured to physically move, e.g. along the optical axis 204. Alternatively, the movable condenser lens may be constituted of two or more electro-optical elements (lenses) in which the principle plane of the condenser lens moves with a variation of the strength of the individual electro-optical elements. The (movable) condenser lens may be configured to be magnetic, electrostatic or a combination of magnetic and electrostatic lenses. In some embodiments, the condenser lens 210 may be an anti-rotation condenser lens. The anti-rotation condenser lens may be configured to keep the rotation angles unchanged when the focusing power (collimating power) of condenser lens 210 is changed and/or when the principle plane of the condenser lens moves.

In some embodiments, the source conversion unit 220 may comprise an image-forming element array, an aberration compensator array, a beam-limit aperture array, and a pre-bending micro-deflector array. The pre-bending micro-deflector array may, for example, be optional and may be present in which the condenser lens does not ensure substantially normal incidence of sub-beams originating from the coulomb aperture array onto e.g. the beam-limit aperture array, the image-forming element array, and/or the aberration compensator array. The image-forming element array may be configured to generate the plurality of sub-beams in the multi-beam path, i.e. primary sub-beams 211, 212, 213. The image forming element array may, for example, comprise a plurality electron beam manipulators such as micro-deflectors or micro-lenses (or a combination of both) to influence the plurality of primary sub-beams 211, 212, 213 of primary electron beam 202 and to form a plurality of parallel images (virtual or real) of primary beam crossover 203, one for each of the primary sub-beams 211, 212, and 213. The aberration compensator array may, for example, comprise a field curvature compensator array (not shown) and an astigmatism compensator array (not shown). The field curvature compensator array may, for example, comprise a plurality of micro-lenses to compensate field curvature aberrations of the primary sub-beams 211, 212, and 213. The astigmatism compensator array may comprise a plurality of micro-stigmators to compensate astigmatism aberrations of the primary sub-beams 211, 212, and 213. The beam-limit aperture array may be configured to define the diameters of individual primary sub-beams 211, 212, and 213. FIG. 2 shows three primary sub-beams 211, 212, and 213 as an example, and it should be understood that source conversion unit 220 may be configured to form any number of primary sub-beams. Controller 50 may be connected to various parts of charged particle beam inspection apparatus 100 of FIG. 1, such as source conversion unit 220, electron detection device 240, primary projection apparatus 230, or motorized stage 209. As explained in further detail below, controller 50 may perform various image and signal processing functions. Controller 50 may also generate various control signals to govern operations of the charged particle beam inspection apparatus, including the charged particle multi-beam apparatus.

Condenser lens 210 may further be configured to adjust electric currents of primary sub-beams 211, 212, 213 down-beam of source conversion unit 220 by varying the focusing power (collimating power) of condenser lens 210. Alternatively, or additionally, the electric currents of the primary sub-beams 211, 212, 213 may be changed by altering the radial sizes of beam-limit apertures within the beam-limit aperture array corresponding to the individual primary sub-beams.

Objective lens 231 may be configured to focus sub-beams 211, 212, and 213 onto the sample 208 for inspection and, in the current example, may form three probe spots 221, 222, and 223 on the surface of sample 208.

Beam separator 233 may be, for example, a Wien filter comprising an electrostatic dipole field and a magnetic dipole field (not shown in FIG. 2). In operation, beam separator 233 may be configured to exert an electrostatic force by electrostatic dipole field on individual electrons of primary sub-beams 211, 212, and 213. In some embodiments, the electrostatic force is equal in magnitude but opposite in direction to the magnetic force exerted by magnetic dipole field of beam separator 233 on the individual primary electrons of the primary sub-beams 211, 212, and 213. Primary sub-beams 211, 212, and 213 may therefore pass at least substantially straight through beam separator 233 with at least substantially zero deflection angles. The direction of the magnetic force depends on the direction of motion of the electrons while the direction of the electrostatic force does not depend on the direction of motion of the electrons. So because the secondary electrons and backscattered electrons generally move in an opposite direction compared to the primary electrons, the magnetic force exerted on the secondary electrons and backscattered electrons will no longer cancel the electrostatic force and as a result the secondary electrons and backscattered electrons moving through the beam separator 233 will be deflected away from the optical axis 204.

Deflection scanning unit 232, in operation, is configured to deflect primary sub-beams 211, 212, and 213 to scan probe spots 221, 222, and 223 across individual scanning areas in a section of the surface of sample 208. In response to incidence of primary sub-beams 211, 212, and 213 or probe spots 221, 222, and 223 on sample 208, electrons are generated from the sample 208 which include secondary electrons and backscattered electrons. In the current example, the secondary electrons propagate in three secondary electron beams 261, 262, and 263. The secondary electron beams 261, 262, and 263 typically have secondary electrons (having electron energy ≤50 eV) and may also have at least some of the backscattered electrons (having electron energy between 50 eV and the landing energy of primary sub-beams 211, 212, and 213). The beam separator 233 is arranged to deflect the path of the secondary electron beams 261, 262, and 263 towards the secondary projection apparatus 250. The secondary projection apparatus 250 subsequently focuses the path of secondary electron beams 261, 262, and 263 onto a plurality of detection regions 241, 242, and 243 of electron detection device 240. The detection regions may, for example, be the separate detection elements 241, 242, and 243 that are arranged to detect corresponding secondary electron beams 261, 262, and 263. The detection regions may generate corresponding signals which are, for example, sent to controller 50 or a signal processing system (not shown), e.g. to construct images of the corresponding scanned areas of sample 208.

The detection elements 241, 242, and 243 may detect the corresponding secondary electron beams 261, 262, and 263. On incidence of secondary electron beams with the detection elements 241, 242 and 243, the elements may generate corresponding intensity signal outputs (not shown). The outputs may be directed to an image processing system (e.g., controller 50). Each detection element 241, 242, and 243 may comprise one or more pixels. The intensity signal output of a detection element may be a sum of signals generated by all the pixels within the detection element.

The controller 50 may comprise image processing system that includes an image acquirer (not shown) and a storage device (not shown). For example, the controller may comprise a processor, computer, server, mainframe host, terminals, personal computer, any kind of mobile computing devices, and the like, or a combination thereof. The image acquirer may comprise at least part of the processing function of the controller. Thus the image acquirer may comprise at least one or more processors. The image acquirer may be communicatively coupled to an electron detection device 240 of the apparatus 40 permitting signal communication, such as an electrical conductor, optical fiber cable, portable storage media, IR, Bluetooth, internet, wireless network, wireless radio, among others, or a combination thereof. The image acquirer may receive a signal from electron detection device 240, may process the data comprised in the signal and may construct an image therefrom. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. The storage may be a storage medium such as a hard disk, flash drive, cloud storage, random access memory (RAM), other types of computer readable memory, and the like. The storage may be coupled to the image acquirer and may be used for saving scanned raw image data as original images, and post-processed images.

The image acquirer may acquire one or more images of a sample based on an imaging signal received from the electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time period. The multiple images may be stored in the storage. The controller 50 may be configured to perform image processing steps with the multiple images of the same location of sample 208.

The controller 50 may include measurement circuitry (e.g., analog-to-digital converters) to obtain a distribution of the detected secondary electrons. The electron distribution data, collected during a detection time window, may be used in combination with corresponding scan path data of each of primary sub-beams 211, 212, and 213 incident on the sample surface, to reconstruct images of the sample structures under inspection. The reconstructed images may be used to reveal various features of the internal or external structures of sample 208. The reconstructed images m thereby be used to reveal any defects that may exist in the sample.

The controller 50 may, e.g. further control the motorized stage 209 to move the sample 208 during, before or after inspection of the sample 208. In some embodiments, the controller 50 may enable the motorized stage 209 to move sample 208 in a direction, e.g. continuously, for example at a constant speed, at least during sample inspection. The controller 50 may control movement of the motorized stage 209 so that the speed of the movement of the sample 208 changes, e.g. dependent on various parameters. For example, the controller may control the stage speed (including its direction) depending on the characteristics of the inspection steps of scanning process.

Although FIG. 2 shows that apparatus 40 uses three primary electron sub-beams, it is appreciated that apparatus 40 may use two or more number of primary electron sub-beams. The present disclosure does not limit the number of primary electron beams used in apparatus 40.

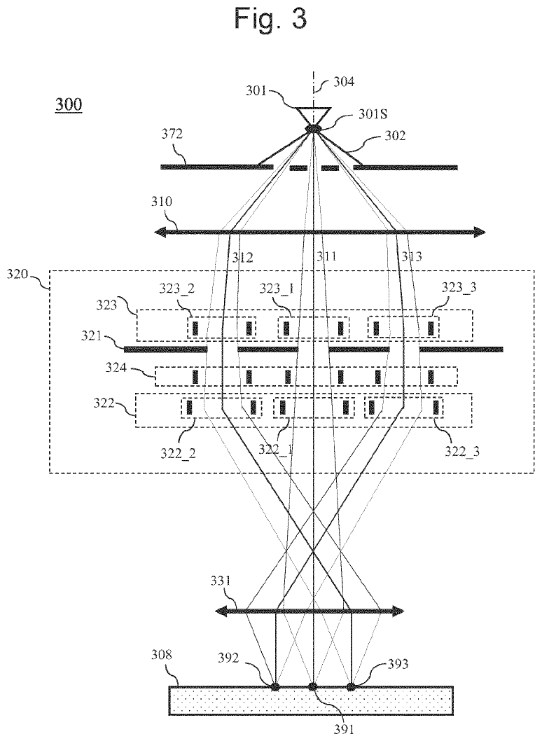

Reference is now made to FIG. 3, which is a schematic diagram of exemplary multi-beam apparatus illustrating an exemplary configuration of source conversion unit of the exemplary charged particle beam inspection apparatus of FIG. 1. The apparatus 300 may comprise an election source 301, a pre-sub-beam-forming aperture array 372 (further also referred to as coulomb aperture array 372), a condenser lens 310 (similar to condenser lens 210 of FIG. 2), a source conversion unit 320, an objective lens 331 (similar to objective lens 231 of FIG. 2), and a sample 308 (similar to sample 208 of FIG. 2). The election source 301, the coulomb aperture array 372, the condenser lens 310 may be the components of an illumination apparatus comprised by the apparatus 300. The source conversion unit 320 and objective lens 331 may be the components of a projection apparatus comprised by the apparatus 300. The source conversion unit 320 may be similar to source conversion unit 220 of FIG. 2 in which the image-forming element array of FIG. 2 is image-forming element array 322, the aberration compensator array of FIG. 2 is aberration compensator array 324, the beam-limit aperture array of FIG. 2 is beamlet-limit aperture array 321, and the pre-bending micro-deflector array of FIG. 2 is pre-bending micro-deflector array 323. The election source 301, the coulomb aperture array 372, the condenser lens 310, the source conversion unit 320, and the objective lens 331 are aligned with a primary electron-optical axis 304 of the apparatus. The electron source 301 generates a primary-electron beam 302 generally along the primary electron-optical axis 304 and with a source crossover (virtual or real) 301S. The coulomb aperture array 372 cuts the peripheral electrons of primary electron beam 302 to reduce a consequential Coulomb effect. The primary-electron beam 302 may be trimmed into a specified number of sub-beams, such as three sub-beams 311, 312 and 313, by the coulomb aperture array 372 of a pre-sub-beam-forming mechanism. Although three sub-beams and their paths are referred to in the previous and following description, it should be understood that the description is intended to apply an apparatus, tool, or system with any number of sub-beams.

The source conversion unit 320 may include a beamlet-limit aperture array 321 with beam-limit apertures configured to define the outer dimensions of the sub-beams 311, 312, and 313 of the primary electron beam 302. The source conversion unit 320 may also include an image-forming element array 322 with image-forming micro-deflectors, 322_1, 322_2, and 322_3. There is a respective micro-deflector associated with the path of each sub-beam. The micro-deflectors 322_1, 322_2, and 322_3 are configured to deflect the paths of the sub-beams 311, 312, and 313 towards the electron-optical axis 304. The deflected sub-beams 311, 312 and 313 form virtual images (not shown) of source crossover 301S. In the current example, these virtual images are projected onto the sample 308 by the objective lens 331 and form probe spots thereon, which are the three probe spots, 391, 392, and 393. Each probe spot corresponds to the location of incidence of a sub-beam path on the sample surface. The source conversion unit 320 may further comprise an aberration compensator array 324 configured to compensate aberrations that may be present in each of the sub-beams. The aberration compensator array 324 may, for example, include a field curvature compensator array (not shown) with micro-lenses. The field curvature compensator and micro-lenses may, for example, be configured to compensate the individual sub-beams for field curvature aberrations evident in the probe spots, 391, 392, and 393. The aberration compensator array 324 may include an astigmatism compensator array (not shown) with micro-stigmators. The micro-stigmators may, for example, be controlled to operate on the sub-beams to compensate astigmatism aberrations that are otherwise present in the probe spots, 391, 392, and 393.

The source conversion unit 320 may further comprise a pre-bending micro-deflector array 323 with pre-bending micro-deflectors 323_1, 323_2, and 323_3 to bend the sub-beams 311, 312, and 313 respectively. The pre-bending micro-deflectors 323_1, 323_2, and 323_3 may bend the path of the sub-beams onto the beamlet-limit aperture array 321. In some embodiments, the pre-bending micro-deflector array 323 may be configured to bend the sub-beam path of sub-beams towards the orthogonal of the plane of on beamlet-limit aperture array 321. In an alternative embodiment the condenser lens 310 may adjust the path direction of the sub-beams onto the beamlet-limit aperture array 321. The condenser lens 310 may, for example, focus (collimate) the three sub-beams 311, 312, and 313 to become substantially parallel beams along primary electron-optical axis 304, so that the three sub-beams 311, 312, and 313 incident substantially perpendicularly onto source conversion unit 320, which may correspond to the beamlet-limit aperture array 321. In some embodiments, the pre-bending micro-deflector array 323 may not be necessary.

The image-forming element array 322, the aberration compensator array 324, and the pre-bending micro-deflector array 323 may comprise multiple layers of sub-beam manipulating devices, some of which may be in the form or arrays, for example: micro-deflectors, micro-lenses, or micro-stigmators.

In the current example of the source conversion unit 320, the sub-beams 311, 312 and 313 of the primary electron beam 302 are respectively deflected by the micro-deflectors 322_1, 322_2 and 322_3 of image-forming element array 322 towards the primary electron-optical axis 304. It should be understood that the sub-beam 311 path may already correspond to the electron-optical axis 304 prior to reaching micro-deflector 322_1, accordingly the sub-beam 311 path may not be deflected by micro-deflector 322_1.

The objective lens 331 focuses the sub-beams onto the surface of the sample 308, i.e., it projects the three virtual images onto the sample surface. The three images formed by three sub-beams 311 to 313 on the sample surface form three probe spots 391, 392 and 393 thereon. In some embodiments, the deflection angles of sub-beams 311 to 313 are adjusted to pass through or approach the front focal point of objective lens 331 to reduce or limit the off-axis aberrations of three probe spots 391 to 393.

In the example of a multi-beam inspection tool 300 as shown in FIG. 3 the beam path of the secondary electrons, beam separator (similar as Wien filter 233), secondary projection optics (similar as secondary projection optics 250 of FIG. 2) and electron detection device (similar as electron detection device 240) have been omitted for clarity reasons. Is should be clear however that similar beam separator, secondary projection optics and electron detection device may be present in the current example of FIG. 3 to register and generate an image of the sample surface using the secondary electrons or backscattered electrons.

At least some of the above-described components in FIG. 2 and FIG. 3 may individually, or in combination with each other, be referred to as a manipulator array, or manipulator, because they manipulate one or more beams, or sub-beams, of charged particles.

The above-described embodiments of multi-beam inspection tools comprise a multi-beam charged particle apparatus, that may be referred to as a multi-beam charged particle optical apparatus, with a single source of charged particles. The multi-beam charged particle apparatus comprises an illumination apparatus and a projection apparatus. The illumination apparatus may generate a multi-beam of charged particles from the beam of electrons from the source. The projection apparatus projects a multi-beam of charged particles towards a sample. At least part of the surface of a sample may be scanned with the multi-beam of charged particles.

A multi-beam charged particle apparatus comprises one or more electron-optical devices for manipulating the sub-beams of the multi-beam of charged particles. The applied manipulation may be, for example, a deflection of the paths of sub-beams and/or a focusing operation applied to the sub-beams. The one or more electron-optical devices may comprise MEMS or micro-electro(nic) mechanical systems.

The charged particle apparatus may comprise beam path manipulators located up-beam of the electron-optical device and, optionally, in the electron-optical device. Beam paths may be manipulated linearly in directions orthogonal to the charged particle axis, i.e. optical axis, by, for example, two electrostatic deflector sets operating across the whole beam. The two electrostatic deflector sets may be configured to deflect the beam path in orthogonal directions. Each electrostatic deflector set may comprise two electrostatic deflectors located sequentially along the beam path. The first electrostatic deflector of each set applies a correcting deflection and the second electrostatic deflector restores the beam to the correct angle of incidence on the electron-optical device. The correcting deflection applied by the first electrostatic deflector may be an over correction so that the second electrostatic deflector can apply a deflection for ensuring the desired angle of incidence to the MEMS. The location of the electrostatic deflector sets could be at a number of locations up-beam of the electron-optical device. Beam paths may be manipulated rotationally. Rotational corrections may be applied by a magnetic lens. Rotational corrections may additionally, or alternatively, be achieved by an existing magnetic lens such as the condenser lens arrangement.

Throughout the present document, the direction of a single beam, or multi-beam, on approach of a sample, which may be a substrate W, may be defined as being substantially along a z-axis. The z-axis may be substantially aligned with the paths of the single beam, or sub-beams. The illuminated surface of the sample may substantially be defined as being in the x-y plane. In scanning operation, a sample may be moved in the x-y plane, and not in the z-direction.

Vibrations may affect the performance of a charged particle apparatus. In particular, the imaging quality of the extremely small features of a substrate may be severely worsened if the SEM and/or substrate W are affected by vibrations. Accordingly, it is necessary to substantially isolate the SEM and substrate W from the main source of vibrations. The main sources of vibrations are floor vibrations, internal base frame vibrations, substrate stage movement induced vibrations and vacuum pump vibrations.

A charged particle apparatus may be described as comprising a charged particle beam generator and a platform for supporting the charged particle beam generator. The charged particle beam generator generates one or more charged particle beams for illuminating a substrate. The platform for supporting the charged particle beam generator provides all of the structures and mechanisms for allowing complete processes with the charged particle beams to be performed.

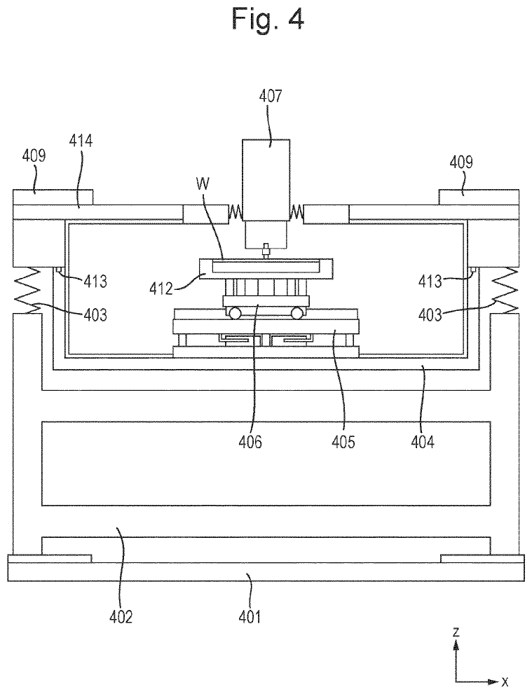

FIG. 4 shows a known charged particle beam apparatus. There is a single beam charged particle beam generator as well as a known platform for supporting the single beam charged particle beam generator.

The single beam charged particle beam generator comprises a single beam SEM 407. The single beam charged particle beam generator may comprise other components, such as an ion pump, that are not shown in FIG. 4. The platform for supporting the SEM 407 comprises frames 402, 414, a chamber 404 and other structures for supporting the operation of the SEM 407.

In particular, the platform comprises a pedestal 401 that sits on the floor. A base frame 402 sits on the pedestal 401. Air mounts 403 are provided between the base frame 402 and an upper part of the platform. The upper part of the platform comprises an upper frame 414 and a chamber 404. Supported by a lower surface of the chamber is a Y long strike drive 405 for moving a substrate support 412 in the Y-direction. Supported by the Y long stroke drive 405 is an X long strike drive 406 for moving the substrate support 412 in the X-direction. Supported by the X long strike drive 406 is the substrate support 412 for holding a substrate W. The upper part of the platform also comprises pumps 409 for generating a substantial vacuum in the chamber 404. The pumps 409 may be mounted via rubber dampers onto the chamber 404 to reduce the pump vibrations that may reach the SEM 407. Within the chamber various sensors and lasers may be provided (not shown in FIG. 4).

In use, the lower part of the chamber 404 is coupled to the upper part of the chamber 404 so that the chamber 404 may be vacuumized. However, the lower part of chamber 404 may be decoupled from the upper part of the chamber 404, as may be required for servicing. There is an O-ring seal 413 that seals the interface between the upper and lower parts of chamber 404 when they are coupled to each other. The O-ring seal 413 allows the chamber 404 to be vacuumized.

With the above-described arrangement of a single beam charged particle apparatus, the upper part of platform is supported on the base frame 402 by air mounts 403 and this substantially isolates the upper part of the platform, including the SEM 407 and substrate support 412, from floor and internal base frame vibrations. Although vibrations occur due to the movement of the substrate support 412, the movement speeds of the substrate support are relatively slow and so the magnitude of the vibrations is relatively low. The waiting time for the magnitude of the vibrations to reduce is also acceptable. The single beam charged particle apparatus may therefore be operated so that the adverse effects of the vibrations that occur due to the movement of the substrate support 412 are tolerable.

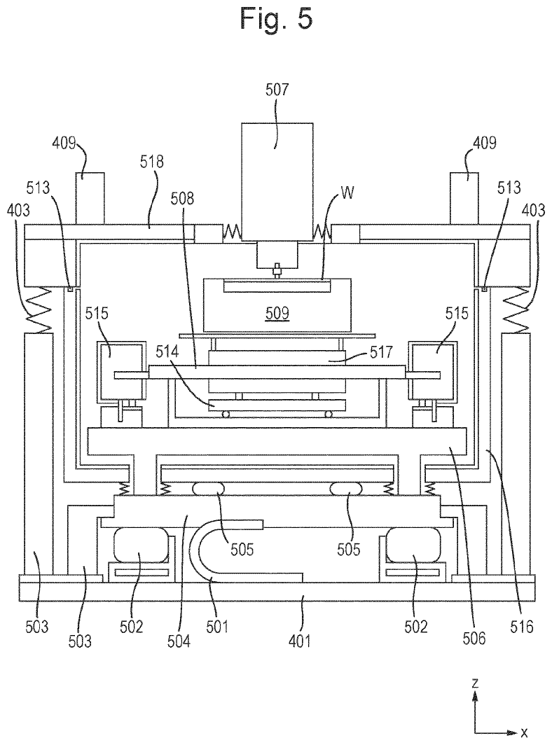

FIG. 5 shows a known charged particle beam apparatus. There is a multi-beam charged particle beam generator as well as a known platform for supporting the multi-beam charged particle beam generator.

The multi-beam charged particle beam generator comprises a multi-beam SEM 507 that may have an ion pump (not shown in FIG. 5). The platform for supporting the SEM 507 comprises frames 503, 518, a chamber 516 and other structures for supporting the operation of the SEM 507.

The platform comprises a pedestal 401 that sits on the floor. A base frame 503 sits on the pedestal 401. Air mounts 403 are provided between the base frame 503 and an upper part of the platform. The upper part of the platform comprises an upper frame 518 and a chamber 516. The chamber 516 comprises a substrate stage frame 506. The substrate stage frame 506 is substantially isolated from the main walls of the chamber 516. The substrate stage frame 506 is supported by a substrate stage interface frame 504. The substrate stage interface frame 504 is outside of the chamber 516. There are openings in the main walls of the chamber 516 for mechanical feedthroughs, i.e. supports, between the substrate stage frame 506 and the substrate stage interface frame 504. There are lifting bellows 502 and an aorta 501 for supporting the substrate stage interface frame 504 on the pedestal 401. There are also chamber bellows 505 for supporting the chamber 516 on the substrate stage interface frame 504.

Supported on an upper surface of the substrate stage frame 506 is an X long strike drive 514 for moving a substrate support in the X-direction. There are balance masses 515 for reducing vibrations resulting from movements by the X long strike drive 514. Supported by the X long stroke drive 514 is a Y long strike drive 508 for moving the substrate support in the Y-direction. Although not shown in FIG. 5, there may also be balance masses for reducing vibrations resulting from movements by the Y long strike drive 508.

Supported by the Y long strike drive 508 is a long stroke carrier 517. The long stroke carrier 517 supports a short stroke arrangement 509 that comprises the substrate support for holding the substrate W. The short stroke arrangement 509 may float above, i.e. not be connected to, the long stroke carrier 517. The short stroke arrangement 509 may be supported by, for example, Lorenz motors. The short stroke arrangement 509 is thereby isolated from vibrations caused by the X and Y long stroke drives 514, 508.

Within the chamber various lasers and sensors may be provided (not shown in FIG. 5). There are also pumps 409 for vacuumizing the chamber 516. The pumps 409 may be mounted via rubber dampers onto the chamber 516 to reduce the pump vibrations that may reach the SEM 507. The lower part of chamber 516 may be decoupled from the upper part of the chamber 516, as may be required for servicing. There is an O-ring 513 that seals the upper and lower parts of the chamber 516 when they are coupled together so that the chamber 516 may be vacuumized.

In the above-described platform for a multi-beam charged particle apparatus, the substrate stage interface frame 504 is used to support the substrate stage frame 506. The substrate stage interface frame 504 acts as a force frame that isolates the movements of the X and Y long stroke drives from the chamber 516, and thereby the SEM 507. However, the process of accessing the substrate support for servicing is complicated because both the substrate stage frame 506 and the lower part of the chamber 516 need to be separately lowered and positioned.

The above-described platform for a multi-beam charged particle apparatus has improved vibration isolation performance over the above-described platform for a single beam charged particle apparatus. This allows the multi-beam charged particle apparatus to be operated with higher accelerations and shorter wait times.

A problem that can be identified with the above-described platforms for single and multi-beam charged particle apparatuses is the pumps 409. These require dampers to reduce the vibrations from the pumps 409. However, the dampers reduce the efficiency of the pumps 409 and require additional safety brackets because each damper is not strong enough to hold a pump 409 if it crashes, and substantially increase costs.

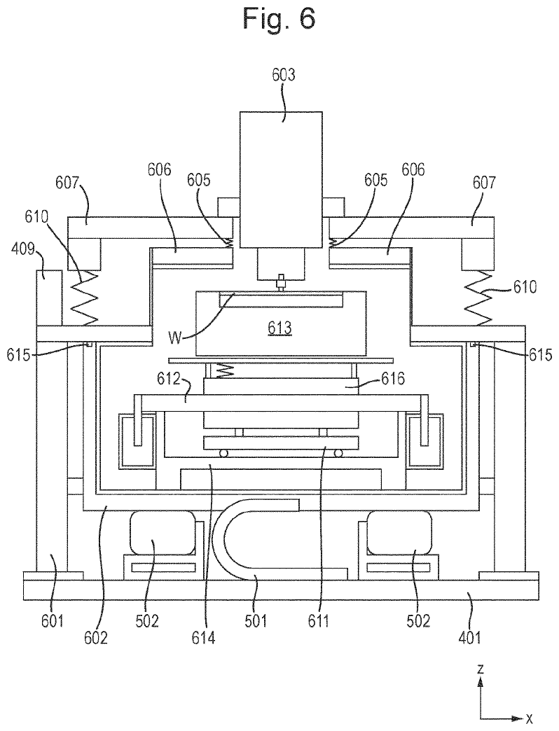

The platform shown in FIG. 5 provides better performance in terms of vibration isolation than the platform shown in FIG. 6. However, the platform shown in FIG. 5 is complicated and has a large footprint. There is a general need to improve the platform for a charged particle apparatus.

There is therefore a general need to provide a new platform with reduced complexity, footprint, and cost than the known platform for a multi-beam charged particle apparatus.

FIG. 6 shows an example multi-beam charged particle apparatus according to some embodiments. This example provides a platform for supporting a multi-beam charged particle beam generator. The multi-beam charged particle beam generator shown in FIG. 6 may be a known multi-beam charged particle beam generator. The platform may alternatively be used to support a known single beam charged particle beam generator.

The multi-beam charged particle beam generator comprises a multi-beam SEM 603 may have an ion pump (not shown in FIG. 6). The platform for supporting the SEM 603 comprises frames 601, 607, a chamber 602 and other structures for supporting the operation of the SEM 603.

The platform comprises a pedestal 401 that sits on the floor. A base frame 601 sits on the pedestal 401. A lower part of the platform comprises a chamber 602. There are lifting bellows 502 and an aorta 501 for supporting the chamber 602 on the pedestal 401. Embodiments also include mechanical spindles, or other techniques for raising and lowering the chamber 602, being used instead of the lifting bellows 502.

The chamber 602 comprises a substrate support arrangement. The substrate support arrangement comprises a substrate stage support 614, X long strike drive 611. Y long strike drive 612, long stroke carrier 616 and short stroke arrangement 613. The substrate stage support 614 is secured to a lower internal surface of the chamber 602. Supported by roller bearing on an upper surface of the substrate stage support 614 is the X long strike drive 611 for moving the long stroke carrier 616 in the X-direction. Supported by the X long stroke drive 611 is the Y long strike drive 612 for moving the long stroke carrier 616 in the Y-direction. Balance masses may be provided on both the X long stroke drive 611 and the Y long strike drive 612 to reduce the vibrations that they cause. The long stroke carrier 616 supports the short stroke arrangement 613 that comprises a substrate support for holding the substrate W. The short stroke arrangement 613 may float above, i.e. not be connected to, the long stroke carrier 616. The short stroke arrangement 613 may be supported by, for example, Lorenz motors. The short stroke arrangement 613 is thereby isolated from vibrations caused by the X and Y long stroke drives 611, 612.

There is an O-ring 615 between an upper part of the chamber 602 and the lower part of the chamber 602. The lower part of the chamber 602 may be decoupled from the upper part of the chamber 602 by lowering the lower part of the chamber 602, as may be required for servicing and other purposes. The O-ring 615 seals the upper and lower parts of the chamber 602 when they are coupled together so that the chamber 602 may be vacuumized.

A metrology frame 607 is comprised by an upper part of the platform. Air mounts 610 may be provided between the base frame 601 and a metrology frame 607. The metrology frame 607 supports the SEM 603.

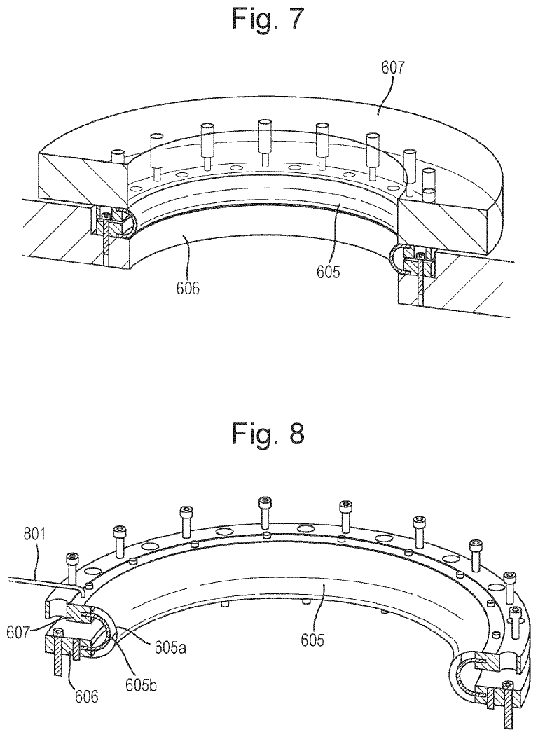

The upper part of the chamber may comprise a chamber upper surface 606 that may be rigidly connected to the base frame 601. The chamber upper surface 606 may comprise an opening so that a charged particle beam from the SEM 603 may enter the chamber 602. The chamber upper surface 606 may be connected to the metrology frame 607 by a bellow 605. The bellow 605 may surround the opening in the chamber upper surface 606. The bellow 605 ensures that the inside of the chamber 602 is part of an enclosed region that a substantial vacuum may be generated in. The bellow 605 may be a flexible member. The flexibility of the bellow 605 substantially isolates the metrology frame 607 from vibrations that are generated in the chamber 602. The bellow 605 is described in more detail later with reference to FIGS. 7 to 9B.

Pumps 409 for generating a substantial vacuum in the chamber 602 may be directly connected to the base frame 601. The metrology frame 607 is isolated from the vibrations from the pumps 409 due to the air mounts 610 and/or bellow 605. Advantageously, the pumps 409 may therefore be connected to the base frame 601 without using rubber dampers and safety brackets.

Within, and/or outside of, the chamber 602 various lasers and sensors may be provided (not shown in FIG. 6). Embodiments include interferometer lasers being mounted on the metrology frame 607 and emitting light into the chamber via viewports. The interferometer lasers may measure the short stroke arrangement 613 position with respect to the SEM 603.

In some embodiments, a new platform for isolating the SEM 603, substrate W and a metrology frame 607 from all of the main vibration sources is provided.

A substrate stage support 614 is mounted on the bottom of the vacuum chamber 602, which is rigidly connected to the base frame 601, to form a single rigid body. The air mounts 610 are placed on the base frame 601. The air mounts 610 carry the metrology frame 607 and SEM 603. The SEM 603 is therefore not rigidly connected to the base frame 601. In some embodiments, a key element in the platform is the flexible bellow 605 between the chamber 602 and the metrology frame 607. The air mounts 610 and bellow 605 limit the vibrations from the pumps 409, floor, base frame 601 and/or chamber 602 (in particular the X and Y long stroke drives 611, 612 in the chamber 602) that may enter the metrology frame 607 and SEM 603. The bellow 605 also ensures that the inside of the chamber 602 is part of an enclosed region that a substantial vacuum may be generated in. The short stroke arrangement 613 is floating above the long stroke carrier 616. This limits the vibrations from the pumps 409, floor, base frame 601 and/or X and Y long stroke drives 611, 612 that may enter the short stroke arrangement 613.

The disclosed platform provides a number of advantages over the known platforms shown in FIGS. 4 and 5.

In particular, the platform has a substantially simpler construction and operation than the known platform for a multi-beam SEM 507, as shown in FIG. 5. The disclosed platform is substantially cheaper to make and operate. The platform also provides similar, or substantially the same, vibration isolation performance and throughput as the known platform for a multi-beam SEM 507.

For example, to provide access to the short stroke arrangement 613 for servicing, the lower part of the chamber 602 may be lowered by deflating the lifting bellows 502. This is performed by a single operation and is therefore simpler, and cheaper, than the processes, as described earlier with reference to FIG. 5, in which both the substrate stage frame 506 and the lower part of the chamber 516 are separately lowered and positioned.

The pumps 409 may be connected to the base frame 601 without using rubber dampers and safety brackets and this is a further cost reduction. This also improves the pump 409 efficiency and so smaller pumps 409 may be used to achieve the same vacuum level.

The load on the metrology frame 607 by the vacuum is reduced. The metrology frame 607 may therefore be smaller and lighter.

The footprint of the platform may also be less than that of the known platform for a multi-beam SEM 507, and similar to the platform for the single-beam SEM 407 as described with reference to FIG. 4.

According to some embodiments, there are provided a number of implementations of the bellow 605 that may be used in the platform.

The bellow 605 may generally be a flexible vibration isolating seal between the metrology frame 607 and the chamber upper surface 606. The bellow 605 has the dual purpose of isolating the metrology frame 607 from vibrations and ensuring that the chamber 602 is a closed structure so that a substantial vacuum may be generated in the chamber. The bellow 605 limits the vibrations from the pumps 409, floor, base frame 601 and/or chamber 602 (in particular the X and Y long stroke drives 611, 612 in the chamber 602) that may enter the metrology frame 607 and SEM 603. The bellow 605 is also a vacuum seal.

FIG. 7 schematically shows a cross-section through a first implementation of a bellow 605 according to some embodiments.

The bellow 605 comprises a single layer of flexible material. The bellow may have a C-shaped cross-section. The bellow 605 has a first end, that may be a lower end, that is secured to the chamber upper surface 606. The lower end of the bellow 605 may be clamped to the chamber upper surface 606 by a metal ring. The bellow 605 has a second end, that may be an upper end, that is secured to the metrology frame 607. The upper end of the bellow 605 may be clamped to the metrology frame 607 by a metal ring. The lower and upper ends of the bellow 605 may be thicker than the rest of the bellow 605 so that each end forms a substantially air tight seal, that may be an O-ring type seal.

In the first implementation, the weight of the metrology frame 607 and SEM 603 is carried by the air mounts 610. The bellow 605 is therefore not load bearing. The bellow 605 may therefore be made from very flexible material that has a low stiffness. The bellow 605 may provide vibration isolation in all degrees of freedom.

In the first implementation of the bellow 605, small amounts of gas may be able to permeate through the bellow 605. The amount of gas permeation may increase as the pressure difference increases across the bellow 605. The amount of gas permeation through the bellow 605 may be tolerable for correct operation of the charged particle apparatus. However, if the amount of gas permeation is not tolerable, then the amount of gas permeation may be decreased by increasing the thickness of the bellow 605. A problem with increasing the thickness of the bellow 605 is that this may decrease the flexibility of the bellow 605 and thereby decrease the vibration isolation performance.

FIG. 8 schematically shows a cross-section through a second implementation of a bellow 605 according to some embodiments.

The bellow 605 comprises two single layers 605b, 605a of flexible material.

A first layer 605b of the bellow 605 may be substantially the same as the above-described first implementation. That is to say, the first layer 605b of the bellow may have a C-shaped cross-section. The first layer 605b has a first end, that may be a lower end, that is secured to the chamber upper surface 606. The lower end of the first layer 605b may be clamped to the chamber upper surface 606 by a metal ring. The first layer 605b has a second end, that may be an upper end, that is secured to the metrology frame 607. The upper end of the first layer 605b may be clamped to the metrology frame 607 by a metal ring. The lower and upper ends of the first layer 605b may be thicker than the rest of the first layer 605b so that each end forms a substantially air tight seal, that may be an O-ring type seal.

A second layer 605a of the bellow 605 may cover the chamber side of the first layer 605b. The second layer 605a may also have a C-shaped cross-section. The second layer 605a has a first end, that may be a lower end, that is secured to the chamber upper surface 606. The lower end of the second layer 605a may be clamped to the upper surface 606 by a metal ring. The second layer 605a has a second end, that may be an upper end, that is secured to the metrology frame 607. The upper end of the second layer 605a may be clamped to the metrology frame 607 by a metal ring. The lower and upper ends of the second layer 605a may be thicker than the rest of the second layer 605a so that each end forms a substantially air tight seal, that may be an O-ring type seal.

A pump may be provided for extracting gas, via an extraction conduit 801, from the enclosed region between the first layer 605b and second layer 605a. The enclosed region between the first layer 605b and second layer 605a may be referred to as a roughing vacuum.

The second implementation of the bellow 605 solves the above-identified potential problem with the first implementation. Any gas that permeates through the first layer 605b flows into the roughing vacuum. The gas may then be removed for the roughing vacuum by the pump. Any gas that permeates through the first layer 605b therefore does not flow into the inside of the chamber 602. The pressure difference between the roughing vacuum and the inside of the chamber may be very small. The second layer 605a may therefore be a lot thinner than the first layer 605b. The second layer 605a therefore does not substantially increase the overall stiffness of the bellow 605.

The second implementation of the bellow 605 may be preferred over the first implementation when the vacuum requirements inside the chamber 602 are extremely high.

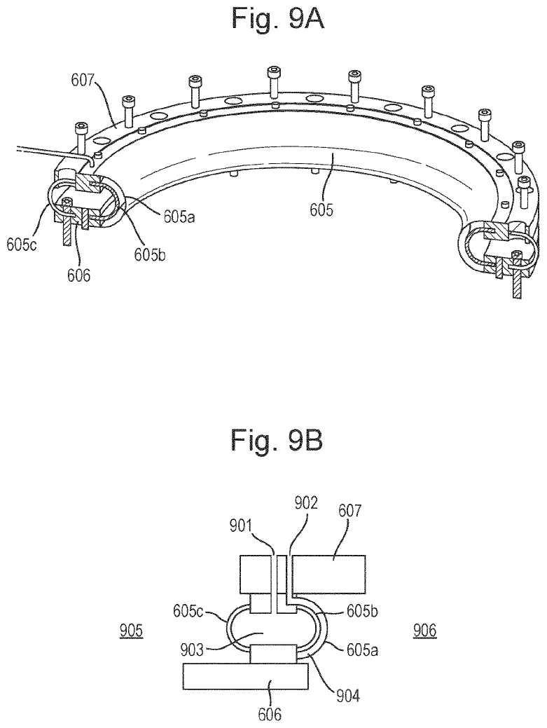

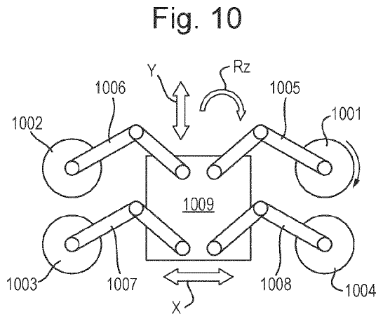

FIGS. 9A and 9B schematically show cross-sections through a third implementation of a bellow 605 according to some embodiments.

The bellow 605 comprises three single layers 605b, 605a, 605c of flexible material.

A first layer 605b and second layer 605a of the bellow 605 may be substantially the same as the above-described second implementation. The third implementation differs from the second implementation by comprising a third layer 605c.

The third layer 605c is on an opposite side of the bellow 605 to the first and second layers. The third layer 605c of the bellow may have a C-shaped cross-section. The third layer 605c has a first end, that may be a lower end, that is secured to the chamber upper surface 606. The lower end of the third layer 605c may be clamped to the chamber upper surface 606 by a metal ring. The third layer 605c has a second end, that may be an upper end, that is secured to the metrology frame 607. The upper end of the third layer 605c may be clamped to the metrology frame 607 by a metal ring. The lower and upper ends of the third layer 605c may be thicker than the rest of the third layer 605c so that each end forms a substantially air tight seal, that may be an O-ring type seal.

In the third implementation, there is a first enclosed region 903 between the third layer 605c and the first layer 605b. There is a second enclosed region 904 between the first layer 605b and the second layer 605a. The first enclosed region 903 may be referred to as the main pressurized region 903. The second enclosed region 904 may be referred to as a roughing vacuum 904.

As described for the second implementation, there may be a pump for removing gas from the roughing vacuum 904. The gas may be removed from the roughing vacuum by flowing through an outflow conduit 902.

The third implementation may also comprise an inflow conduit 901 for gas flow into the main pressurized region 903. There may be a pump, or compressor, for providing the gas flow through the inflow conduit 901. The main pressurized region 903 may be a boundary between an ambient pressure region 905 outside of the chamber 602 and a vacuum region 906 inside of the chamber 602. The pressure in the main pressurized region 903 may be a few bars higher than that of the ambient pressure region 905. The bellow 605 of the third implementation may differ from that of the first and second implementations by being load bearing. That is to say, the weight of the metrology frame 607 and SEM 603 may be entirely carried by the bellow 605. Advantageously, the air mounts 610 may no longer be required and this reduces the complexity, and cost, of the platform for the charged particle apparatus.

Embodiments include the air mounts 610 being replaced by Lorentz actuators with six degrees of freedom. These may be used for fine positioning, drift control, dampening movements of the suspended metrology frame 607 and as a safety measure for allowing the metrology frame to be quickly raised in the in the event of a malfunction occurring (such as a crash of the short stroke arrangement 613).

In all of the above implementations, the material of each layer of the bellow 605 may be, for example, synthetic rubber such as Viton™. Each layer of the bellow 605 may also be made from other materials, including metal.

According to some embodiments, techniques are provided for improving on the known techniques for performing large movements of a substrate W in a charged particle apparatus.

In known charged particle beam apparatuses, large substrate W movements are performed by an X long stroke drive 514 and Y long stroke drive 508 that move a long stroke carrier 517. The long stroke carrier 517 supports a short stroke arrangement 509 that comprises the substrate support for holding the substrate W. The long stroke carrier 517 may be moved linearly by an electromagnetic drive, a guide, a linear (encoder) measurement system, cable slabs and other components. All these parts are placed directly underneath the SEM 507, inside the vacuum chamber 516. There may also be a water-cooling system.

With the above-described known techniques for performing large movements of a substrate W, a large proportion of the volume of the chamber 516 is consumed by the components for moving the substrate W. There are a number of disadvantages of having these components in the chamber 516. The magnetism from magnets, coils and cables may disturb the SEM image. There may be thermal effects, such as the heat dissipation by the motors causing drift and sensitive parts deforming. The outgassing requirement of the chamber 516 may be increased due to grease from the guides and the many cables. This may increase the pump-down times and require turbo pumps. The number of defects may increase due to particles from the guides, other moving parts, and the heavy cable slabs disturbing SEM acquisition, damaging the substrate W and/or damaging the SEM 507. The cost of the long stroke drives and is large and their guides require relatively frequent servicing.

It is therefore preferable for as many components as possible to be mounted outside of the chamber 516. In addition to reducing, or avoiding, the above-identified disadvantages, components that are located outside of the chamber 516 are easily serviceable, without the chamber needing to be de-vacuumized.

According to some embodiments, the motors for performing large movements of the substrate W are moved outside of the chamber. The rotation of motors outside of the chamber may cause large X, Y and optionally Rz movements of a substrate W inside of the chamber.

FIG. 10 schematically shows a plan view of a first implementation of a substrate support movement apparatus according to some embodiments. The substrate support movement apparatus may be referred to as a scara arrangement.

The substrate support movement apparatus comprises a substrate support that is a component for supporting a substrate. The substrate support may comprise long stoke carrier 1009 and short stroke arrangement (not shown in FIG. 10) that may float above the long stroke carrier 1009. The long stroke carrier 1009 and short stroke arrangement may be as described earlier with reference to FIGS. 5 and 6. Accordingly, the short stroke arrangement may be supported above the long stroke carrier 1009 by, for example, Lorenz motors. A substrate W that is secured to the short stroke arrangement is thereby isolated from vibrations caused by the long stroke movements.

The substrate support movement apparatus also comprises a first jointed arm 1005, a second jointed arm 1006, a third jointed arm 1007 and a fourth jointed arm 1008. There is also a first motor 1001, a second motor 1002, a third motor 1003 and a fourth motor 1004. The first jointed arm 1005 may connect an axial shaft of the first motor 1001 to the long stroke carrier 1009. The second jointed arm 1006 may connect an axial shaft of the second motor 1002 to the long stroke carrier 1009. The third jointed arm 1007 may connect an axial shaft of the third motor 1003 to the long stroke carrier 1009. The fourth jointed arm 1008 may connect an axial shaft of the fourth motor 1004 to the long stroke carrier 1009.

Although not shown in FIG. 10, there is a chamber and the long stroke carrier 1009, first jointed arm 1005, second jointed arm 1006, third jointed arm 1007 and fourth jointed arm 1008 are located inside the chamber. The first motor 1001, second motor 1002, third motor 1003 and fourth motor 1004 are located outside of the chamber and the axial shafts of these motors extends through a wall of the chamber. Each axial shaft therefore extends through the chamber wall to an end of a respective jointed arm. The chamber wall may comprise seals so that each of the axial shafts may pass through it. Each seal may be, for example, a ferro-fluid bearing.

The jointed arms 1005, 1006, 1007 and 1008 translate the rotational movements of the axial shafts of each of their respective motors into linear movements of the long stroke carrier 1009 in the X and Y directions, and/or rotation in Rz.

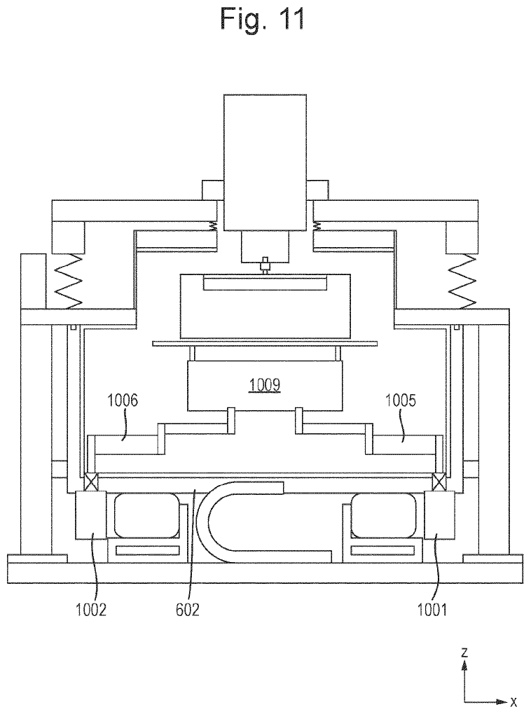

FIG. 11 is a schematic side on view of the first implementation according to some embodiments. According to some embodiments, the substrate support movement apparatus is provided in a disclosed platform for a charged particle apparatus. The third and fourth motors, and their respective jointed arms, are not shown. The motors are all located outside of the chamber 602 and axial shafts of the motors extend up through a bottom wall of the chamber.

In some embodiments, a second implementation of the substrate support movement apparatus is provided. The second implementation differs from the first implementation by comprising only three of the motors, and respective jointed arms, of the first implementation. For example, the second implementation may comprise only the first motor 1001, the second motor 1002 and third motor 1003, as well as their respective jointed arms. The second implementation may otherwise be the same as the first implementation. The second implementation is able to perform X, Y and Rz movements of the long stroke carrier. The second implementation is less expensive than the first implementation because it comprises less motors and jointed arms. However, the first implementation may be preferable over the second implementation because the use of four motors provides additional control, stiffness, force, redundancy, and symmetry.

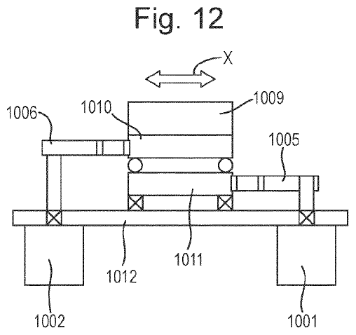

A third implementation of the substrate support movement apparatus according to some embodiments is shown in FIG. 12.

FIG. 12 is a side view of the substrate support movement apparatus according the third implementation. In the third implementation, there are only two motors and respective jointed arms. There is a chamber that comprises a chamber wall 1012. Located within the chamber, there is a long stroke carrier 1009, a first long stroke slide 1011, a second long stroke slide 1010, a first jointed arm 1005 and a second jointed arm 1006. Located outside of the chamber is a first motor 1001 and a second motor 1002. The first jointed arm 1005 may connect the first motor 1001 to the first long stroke slide 1011. The second jointed arm 1006 may connect the second motor 1002 to the second long stroke slide 1010. The long stroke carrier 1009 may be secured on the second long stroke drive 1010. The upper long stroke slide 1010 may be secured to the lower long stroke slide 1011. The lower long stroke slide 1011 may be free to move relative to the lower internal surface of the chamber 1012.

Although not shown in FIG. 12, the long stroke carrier 1009 may support a short stroke arrangement as already described for the first implementation.

In the third implementation, each jointed arm acts on long stroke slide 1010, 1011 instead of the long stroke carrier 1009. Such an arrangement may increase the vertical stiffness, and vertical positioning accuracy, of the long stroke carrier 1009.

The jointed arms 1005 and 1006 translate the rotational movements of the axial shafts of each of their respective motors into linear movements of the long stroke carrier 1009 in the X and Y directions. The third implementation does not provide Rz movement of the long stroke carrier 1009. However, an advantage of the third implementation is that it is substantially less expensive than the first implementation because only two motors are required.

In some embodiments, the first and second implementations are modified according to the third implementation. This is to say, each jointed arm of the first and second implementations acts on long stroke slide instead of the long stroke carrier. Such an arrangement may increase the vertical stiffness, and vertical positioning accuracy, of the long stroke carrier.

All of the implementations of the disclosed techniques/apparatus for moving a substrate may be applied in the platform for a charged particle apparatus, as described earlier with reference to FIG. 6. All of the implementations may also be applied in known platforms for charged particle apparatuses, such as those described earlier with reference to FIGS. 4 and 5.

All of the implementations of the disclosed techniques/apparatus may include the use of counter weights that may be applied to any of the jointed arms or motors. Each counterweight may act to align the center of inertia with a rotational axis.

All of the implementations of the disclosed techniques/apparatus may include the use of rotational encoders in each of the motors. This would avoid the requirement for a linear (encoder) measurement system inside the chamber.

In all of the above-described implementations of the disclosed techniques/apparatus, the active components (i.e. motors) for large movements of the substrate W are all located outside of the chamber. This avoids, or reduces, at least some of the earlier identified problems with known techniques. An additional advantage of the implementations is that less cables are required. The cables that are required may also be routed through, or on, the jointed arms.

According to some embodiments, techniques are provided for improving on the known implementations of balance masses in a platform for a charged particle apparatus.

Known multi-beam SEMs comprise balance masses. The balance masses are arranged to move in the opposite directions to the long stroke drives. The effect of the balance masses is that the vibrations caused by the long stroke movements are reduced. The balance masses used in known multi-beam SEMs are large, heavy, expensive, and active. The balance masses are active because each balance mass is motorized, equipped with an encoder and servo-controlled. The balance masses are so heavy that additional magnetic gravity compensation is required.

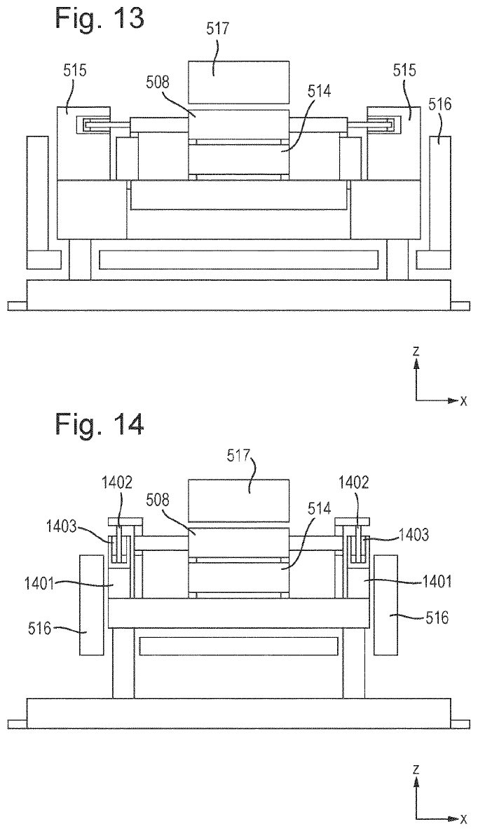

FIG. 13 schematically shows a known implementation of balance masses in a platform for a multi-beam charged particle apparatus. Located with the chamber 516, there is a Y long stroke drive 508 and two corresponding Y-directed active balance masses 515. The reaction forces generated by movement of the Y long stroke drive 508 act against the two Y-directed active balance masses 515 in a counter-balance arrangement. Also located with the chamber 516 is an X long stroke drive 514 and two corresponding X-directed active balance masses. The balance masses for the X long stroke drive 514 are not shown in FIG. 13. As described earlier, a long stroke carrier 517 is supported by the Y long stroke drive 508. The balance masses reduce the magnitude of the reaction forces that are generated and thereby reduce the potential disturbance of the charged particle beam generator.

A number of problems may be identified with the known implementations of balance masses. The balance masses are very expensive. The balance masses are also very heavy, and this complicates their handling, transport, and servicing. The balance masses occupy a large volume. This increases the size of the substrate stage frame and the overall footprint of the charged particle apparatus. The large material stresses complicate the design and manufacture of the guiding. The adjustment and setup of the balance masses is also time consuming.

FIG. 14 schematically shows a balance mass arrangement according to some embodiments. The balance mass arrangement avoids, or reduces, at least some of the above-identified problems. The balance mass arrangement may be implemented in the chamber 516 of the above-described known platform for a multi-beam charged particle apparatus.

The balance masses are a lot less massive than those in the above-described known techniques. The balance masses are at least partially provided by the masses of the long stroke motors.

FIG. 14 shows the long stroke motor magnet stators 1403, i.e. magnet yokes, and motor elements 1402, i.e. motor coils/shaft, for the Y long stroke drive 508. The long stroke motor magnet stators 1403 provide at least part of the mass of the balance mass arrangement for movements by the Y long stroke drive 508. The mass of the long stroke motor magnet stators 1403 may be increased by securing additional masses to them so as to increase the overall mass of the balance mass arrangement for movements by the Y long stroke drive 508.

Although not shown in FIG. 14, there are also long stroke motor magnet stators, i.e. magnet yokes, and motor elements, i.e. motor coils/shaft, for the X long stroke drive 514. The long stroke motor magnet stators provide at least part of the mass of the balance mass arrangement for movements by the X long stroke drive. The mass of the long stroke motor magnet stators may be increased by securing additional masses to them so as to increase the overall mass of the balance mass arrangement for movements by the X long stroke drive.

The Y long stroke drive 508 may be moved by two long stroke motors on opposing sides of the Y long stroke drive 508. The motor element 1402 of each motor moves relative to the motor stator 1403 of the motor. The motor elements 1402 of the two motors may be connected to opposing sides of the Y long stroke drive so as to move the Y long stroke drive.

Similarly, the X long stroke drive 514 may be moved by two long stroke motors on opposing sides of the X long stroke drive 514. The motor element of each motor moves relative to the motor stator of the motor. The motor elements of the two motors may be connected to opposing sides of the X long stroke drive so as to move the X long stroke drive.

Each long stroke motor magnet stator 1403, together with any additional masses, is mounted on flexible damper 1401. Each flexible damper 1401 may be mounted on a substrate stage frame. The substrate stage frame may be substantially isolated from the chamber 516, by mechanical feedthroughs, i.e. supports, between the substrate stage frame and a substrate stage interface frame, as shown in FIG. 14 and described earlier with reference to FIG. 5.

Each flexible damper 1401 may be, for example, an elastic leaf spring that may be metallic. The balance masses are relatively light weight and so the flexible dampers 1401 may have a relatively simple, compact and low-cost design with low stresses. The flexible dampers 1401 provide a passive balance mass arrangement.

Unlike an active balance mass arrangement, the passive balance mass arrangement is not motorized. The passive balance mass arrangement may apply damping by, for example, eddy current damping and/or with rubber elements. Eddy current damping may be implemented by adding a second magnet track which moves relative to an aluminum plate. For the rubber elements, the rubber may be vulcanized onto the leaf springs. The passive balance mass arrangement may comprise balance mass encoders for magnetic commutation of the long stroke motors. The balance mass encoders may only be required for movements that are, for example, greater than 1 mm.

In known techniques, the long stroke motor magnet stators and the motor elements are orientated in the X-Y plane. In some embodiments of the present disclosure, the long stroke motor magnet stators 1403 and parts of the motor elements 1402, i.e. motor coils/shaft, that are located in the long stroke motor magnet stators 1403 may differ by being orientated in the z-direction (i.e. orientated in a direction that is orthogonal to the directions that the long stoke drives move in). Advantageously, this reduces the footprint of the substrate stage frame and the overall footprint of the charged particle apparatus.

Advantageously, the balance mass arrangement does not comprise the large, heavy, and expensive balance masses and gravity compensators of known techniques. There is also no need for a base plate, i.e. a balance mass sub-frame, and this reduces costs as well as the overall mass and volume.

The vibration reduction provided by the passive balance mass arrangement may improve the performance of a multi-beam charged particle apparatus by between 10 and 100 times compared to when no balance masses are used. The passive balance mass arrangement may be substantially cheaper than the known active balance mass arrangements. The passive balance mass arrangement may be substantially less massive than known active balance mass arrangements. This simplifies its servicing, handling, and transport. The footprint of a charged particle apparatus with the passive balance mass may be less than when an active balance mass is used. The use of the passive balance mass arrangement may also result in the installation and servicing of the substrate stage frame being easier and quicker.

The balance mass arrangement has been described as implemented in the above-described known platform for a multi-beam charged particle apparatus. The balance mass arrangement may also be implemented in the platform for a charged particle apparatus described above, as well as other types of apparatus. In particular, the balance mass arrangement/technique includes the substrate stage frame alternatively being directly mounted on a lower surface of the chamber, as described earlier with reference to FIG. 6.

According to some embodiments, techniques are provided for reducing the magnitude of the vibrations in the frame of a charged particle apparatus.

The frame of a charged particle apparatus may comprise a base frame that sits on a pedestal that is located on a floor. There may also be metrology frame for supporting a SEM. There may also be stage frame for supporting components such as the substrate stage. The stage frame may be comprised by the base frame. All of these frames may be integral with each other, or some of them may be separate by, for example, air mounts.

The main potential sources of vibrations in a frame of a charged particle apparatus are floor vibrations and stage acceleration forces. Any frame vibrations that reach a charged particle beam generator may degrade the performance of the charged particle apparatus. There are components, such as air mounts, that may substantially reduce the magnitude of the frame vibrations that reach the charged particle beam generator. However, the vibration isolation provided by these components may not be sufficient for large magnitude frame vibrations and so there is a general need to minimize the frame vibrations. Furthermore, the dynamic, or modal, behavior of frames may magnify the frame vibrations. The frame vibrations may therefore have a relatively large magnitude at resonant frequencies of the frame.

There is also a general desire for the footprint of charged particle apparatuses to be reduced, and/or not substantially increased as the charged apparatuses are further developed. There is therefore a trend for charged particle apparatuses to be made increasingly taller. However, increasing the height of a frame for a given footprint may increase the magnitude of the frame vibrations.

The frame of a charged particle apparatus supports various modules, such as electrical cabinets, flow, and temperature cabinets, etc. These modules add significant mass to the overall mass of the platform, i.e. the frame and modules. The magnitude of vibrations in the frame may be reduced by increasing the stiffness of the frame. Increasing the stiffness increases the Eigen frequencies. However, due to the relatively large mass of the modules, increasing the stiffness requires adding a substantial amount of material to the frame. This may substantially increase both the mass and cost of the frame.

In some embodiments, a frame is provided for a platform of a charged particles apparatus that may have improved vibration performance over known frames.

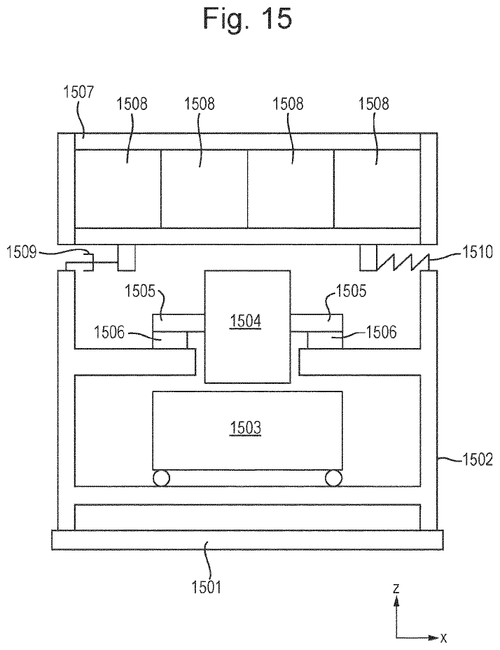

FIG. 15 schematically shows a first implementation of a frame of a platform for a charged particle apparatus according to some embodiments.

The frame comprises a base frame 1502, a metrology frame 1505 and a top frame 1507. The base frame may be mounted on a pedestal 1501 on the floor. The base frame 1502 may alternatively be mounted directly onto the floor. The metrology frame 1505 supports a charged particle beam generator 1504, that may be either a single beam charged particle beam generator or a multi-beam charged particle beam generator. The metrology frame 1505 is connected to the base frame via air mounts 1506. The base frame 1502 comprises a stage frame that supports components such as the substrate stage 1503. The top frame 1507 comprises one or more modules 1508. The modules may include electrical cabinets, flow and temperature cabinets, and other types of cabinet. Each of the modules 1508 may be relatively large and heavy.

In the first implementation, the top frame 1507 is connected to the base frame 1502 via a frame connecting devices 1509, 1510. The frame connecting devices 1509, 1510 have a well-defined stiffness and damping. Due to the frame connecting devices 1509, 1510, the top frame 1507 is not rigidly connected to the base frame 1502. The frame connecting devices 1509, 1510 may both be the same as each other. Each frame connecting device 1509, 1510 may comprise, for example, a spring or bellow for providing a well-defined stiffness. Each frame connecting device 1509, 1510 may comprise, for example, a damping mechanism. The damping mechanism may, for example, be passive such as a rubber element, an eddy current damping system, or an oil damper. Alternatively, the damping mechanism may be active, such as a Lorenz or reluctance actuator arranged in parallel to a spring, or a piezo stack may be used.

The effect of the frame connecting devices 1509, 1510 is to establish a resonance between the top frame 1507 and the base frame 1502. The resonance response is dependent on the stiffness and damping of the frame connecting devices 1509, 1510. The stiffness and damping of the frame connecting devices 1509, 1510 may therefore be set so as to provide a desired resonance response of the base frame 1502 that reduces the magnitude of the frame vibrations that may occur.

The resonance response may be configured as either tuned mass damping system or a sky mass damping system.

In a tuned mass damping system, the stiffness and damping of the frame connecting devices 1509, 1510 are set so that the resonant frequency of the top frame 1507 and base frame 1502 is substantially the same as a resonant frequency of the base frame 1502. The resonant frequency of the base frame 1502 is dependent on the internal stiffness of the base frame 1502. The tuned mass damping may substantially reduce the magnitude of frame vibrations at the resonant frequency that it is tuned to.

In a sky mass damping system, the stiffness and damping of the frame connecting devices 1509, 1510 are set so that the resonant frequency of the top frame 1507 and base frame 1502 is substantially less than the lowest resonant frequency of the base frame 1502. For example, the resonant frequency of the top frame 1507 and base frame 1502 may be 5 to 10 times less than the lowest resonant frequency of the base frame 1502. This substantially decouples the mass of the top frame 1507 from the base frame 1502. The top frame 1507 may effectively be a substantially stationary mass with a damper connected to the base frame 1502. The sky mass damping may reduce the magnitude of frame vibrations over a wide range of frequencies.

An advantage of a tuned mass damping system is that the dampening mass provided by the top frame 1507 does not need to be large. For example, the mass of the top frame 1507 may be one tenth of the modal mass of the base frame 1502 at the resonant frequency that it is tuned to. A disadvantage of the tuned mass damping system is that there may be relatively large movements of the top frame 1507. This may prevent modules 1508 that comprise components that are adversely affected by such movements from being located in the top frame 1507.

An advantage of the sky mass damping system is that the top frame 1507 remains substantially stationary. Any module 1508 may therefore be relocated to the top frame 1507. However, a disadvantage of the sky mass damping system is that the top frame 1507 may need to have a large dampening mass.

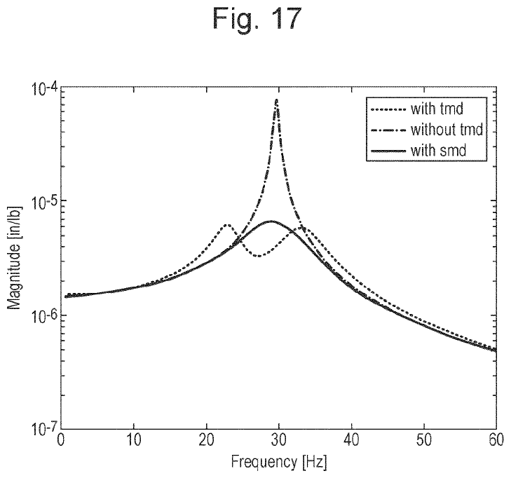

FIG. 17 shows the magnitude of frame vibrations caused by a resonant frequency of the base frame 1502 when there is: neither tuned mass damping nor a sky mass damping (shown by a dash-dot line), only tuned mass damping (shown with a dotted line), and only sky mass damping (shown with a sold line). It is clear that both the tuned mass damping and sky mass damping substantially reduce the magnitude of the frame vibration at the resonant frequency.

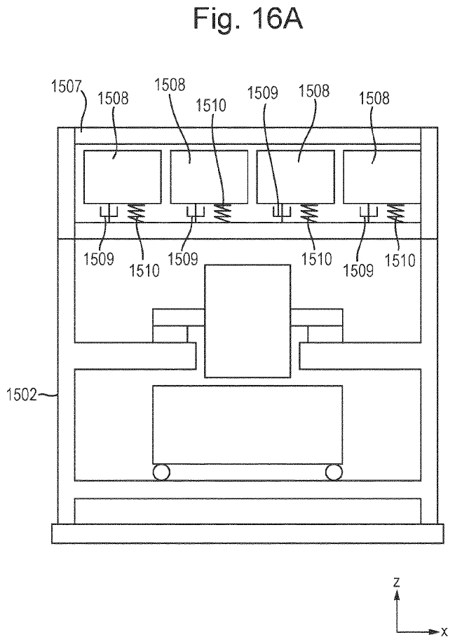

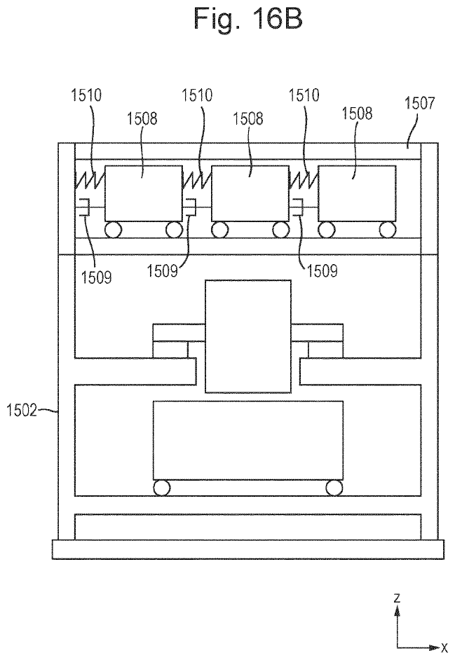

FIG. 16A shows a second implementation of the frame according to some embodiments.

The second implementation differs from the first implementation by the top frame being rigidly connected to the base frame 1503. The one or more modules 1508 comprised by the top frame are each connected to the top frame by module connecting devices 1509, 1510. The module connecting devices 1509, 1510 may be the same as, or similar to, any of the different types of frame connecting device 1509, 1510 as described earlier for the first implementation.

In the second implementation, the modules 1508 are substantially independent from each other. The types, stiffness and/or dampening of the module connecting devices 1509, 1510 may differ between the modules 1508. This may allow flexibility in the configuration of the tuned and/or sky mass dampening system. In particular, the dampening system may be a hybrid of both a tuned mass dampening system and a sky mass dampening system. For example, the resonance between one or more of the modules 1508 and the base frame 1502 may be substantially the same as a resonant frequency of the base frame 1502 (as in a tuned mass dampening system). The resonance between one or more of the modules 1508 and the base frame 1502 may also be substantially less than the resonant frequency of the base frame 1502 (as in a sky mass dampening system).

FIG. 16B shows a third implementation of the frame according to some embodiments.

The third implementation differs from the first implementation by the top frame 1507 being rigidly connected to the base frame 1502. At least one module 1508 comprised by the top frame 1507 is connected to the top frame 1507 by a module connecting device 1509, 1510. Each module 1508 may be connected to each adjacent module 1508 to it by a module connecting device 1509, 1510.

The module connecting devices 1509, 1510 may be the same as, or similar to, any of the different types of frame connecting device 1509, 1510 as described earlier for the first implementation.

The third implementation allows flexibility in the configuration of the tuned and/or sky mass dampening system. In the third implementation, the types, stiffness and/or dampening of the module connecting devices 1509, 1510 may differ between the modules 1508. As described for the second implementation, the dampening system of the third implementation may be a hybrid of both a tuned mass dampening system and a sky mass dampening system.

Further implementations include any of the techniques of the first, second and third implementations being used together. For example, the second and/or third implementations may be modified so that the top frame 1507 is connected to the base frame 1502 via frame connecting devices 1509, 1510, as described for the first implementation.

Advantages include the magnitude of frame vibrations being reduced. The footprint of the platform for a charged particle apparatus may also be reduced, due the relocation of modules 1508 to above the charged particle beam generator. The cost of using more frame material to increase the stiffness of the frame is also avoided.

The techniques corresponding to the disclosed frame may be applied together with those of any of the earlier described embodiments. In particular, the disclosed platform may be modified according to the techniques of the disclosed frame. The known platforms shown in FIGS. 4 and 5 may also be modified according to the techniques associated with the disclosed frame.

Embodiments include a number of modifications and variations to the techniques as described above.

In particular, the techniques/implementations described above may be applied together with those of any of one or more of the other embodiments.

Embodiments include the following numbered clauses:
1. A platform for a charged particle apparatus, the platform comprising:
   a base frame;
   a chamber arranged to comprise a substrate;
   a metrology frame arranged to support a charged particle beam generator for irradiating a substrate in the chamber with a charged particle beam; and
   a bellow arranged between the metrology frame and the chamber;
   wherein:
   the chamber is rigidly connected to the base frame;
   the bellow comprises a flexible material such that the metrology frame is substantially isolated from any vibrations that are generated in the chamber; and
   the bellow is air tight so that a substantial vacuum may be established in the chamber.
2. The platform according to clause 1, further comprising air mounts arranged to support the metrology frame on the base frame.
3. The platform according to clause 1 or 2, further comprising a substrate support arrangement within the chamber;
   wherein the substrate support arrangement is rigidly secured to the chamber.
4. The platform according to clause 3, wherein the substrate support arrangement comprises:
   a long stroke arrangement that comprises one or more long stroke drives and a long stroke carrier; and
   a short stroke arrangement that is arranged to support a substrate;
   wherein:
   the long stroke drives are arranged to move the long stroke carrier; and
   the short stroke arrangement is flexibly supported by the long stroke carrier so that the short stroke arrangement is substantially isolated from vibrations that are generated by the long stroke arrangement.
5. The platform according to clause 4, wherein the long stroke carrier comprises one or more Lorenz motors that are arranged so that the short stroke arrangement floats above the long stroke carrier.
6. The platform according to any preceding clause, further comprising one or more pumps for establishing a substantial vacuum in the chamber;
   wherein the one or more pumps are directly connected to the base frame.
7. A charged particle apparatus comprising:
   a platform of any preceding clause; and
   a charged particle beam generator.
8. The charged particle apparatus according to clause 7, wherein the charged particle beam generator is arranged to emit a multi-beam of charged particles.
9. A bellow for proving a connection between a vacuum chamber and a metrology frame in a platform for a charged particle apparatus, the bellow comprising:
   a layer of material arranged in a loop;
   wherein:
   the material is flexible and substantially air tight;
   the layer comprises a first end for securing to the chamber; and
   the layer comprises a second end for securing to the metrology frame.
10. The bellow according to clause 9, wherein the layer is a first layer, and the bellow further comprises:
   a second layer of material arranged in a loop; and
   an outflow conduit;
   wherein:
   the second layer is separated from the first layer so that there is an enclosed region between the first layer and second layer;
   the outflow conduit is arranged to extract gas from the enclosed region;
   the material of the second layer is flexible and substantially air tight;
   the second layer comprises a first end for securing to the chamber; and
   the second layer comprises a second end for securing to the metrology frame.
11. The bellow according to clause 10, wherein the enclosed region is a first enclosed region, the bellow further comprising:
   a third layer of material arranged in a loop; and
   an inflow conduit;
   wherein:
   the third layer is separated from the first layer and on an opposite side of the first layer to the second layer so that there is a second enclosed region between the first layer and second layer;
   the inflow conduit is arranged to provide a gas flow into the second enclosed region;
   the material of the third layer is flexible and substantially air tight;
   the third layer comprises a first end for securing to the chamber; and
   the third layer comprises a second end for securing to the metrology frame.
12. The bellow according to clause 11, wherein:
   the inflow conduit is arranged to pressurise the second enclosed region to a higher pressure than the ambient pressure around the platform;
   the outflow conduit is arranged to extract gas from the first enclosed region so that the first enclosed region is at a substantially lower pressure than the second enclosed region.
13. The bellow according to any of clauses 9 to 12, wherein the material of the first, second and/or third layer is rubber.
14. A platform for a charged particle apparatus comprising:
   a chamber;
   a metrology frame; and
   a bellow according to any of clauses 9 to 13;
   wherein:
   an inner side of the bellow is arranged to support a substantial vacuum in the chamber; and
   an outer side of the bellow is arranged to withstand the ambient pressure around the platform.
15. A charged particle apparatus comprising:
   a platform according to any of clauses 1 to 6, wherein the platform comprises a bellow according to any of clauses 9 to 13; and
   a charged particle beam generator.
16. A substrate support movement apparatus for moving a substrate in a chamber of a platform for a charged particle apparatus, the substrate support movement apparatus comprising:
   a first motor shaft;
   a second motor shaft;
   a first jointed arm;
   a second jointed arm; and
   a substrate support;
   wherein:
   an end of the first motor shaft is connected to a first end of the first jointed arm;
   an end of the second motor shaft is connected to a first end of the second jointed arm;
   a second end of the first jointed arm is connected to the substrate support; and
   a second end of the second jointed arm is connected to the substrate support.
17. The substrate support movement apparatus according to clause 15, further comprising:
   a third motor shaft; and
   a third jointed arm;
   wherein:
   an end of the third motor shaft is connected to a first end of the third jointed arm; and
   a second end of the third jointed arm is connected to the substrate support.
18. The substrate support movement apparatus according to clause 16, further comprising:
   a fourth motor shaft; and
   a fourth jointed arm;
   wherein:
   an end of the fourth motor shaft is connected to a first end of the fourth jointed arm; and
   a second end of the fourth jointed arm is connected to the substrate support.
19. The substrate support movement apparatus according to any of clauses 16 to 18, wherein, in response to rotation of at least two of the motor shafts, the rotation is translated by at least two of the jointed arms into linear movement of the substrate support.
20. The substrate support movement apparatus according to any of clauses 17 or 18, wherein, in response to rotation of at least three of the motor shafts, the rotation is translated by at least three of the jointed arms into linear or rotational movement of the substrate support.
21. The substrate support movement apparatus according to any of clauses 16 to 20, wherein the substrate support comprises a long stroke carrier; and
   each jointed arm is connected to the long strake carrier.
22. The substrate support movement apparatus according to any of clauses 16 to 20, wherein the substrate support comprises a plurality of slides; and
   each jointed arm is connected to a slide.
23. A substrate movement arrangement for use in a platform of a charged particle apparatus, the substrate movement arrangement comprising:
   a substrate support movement apparatus according to any of clause 16 to 22;
   a chamber; and
   a plurality of motors;
   wherein:
   the substrate support and each jointed arm of the substrate support movement apparatus are located in the chamber;
   each motor shaft of the substrate support movement apparatus is arranged to pass through a wall of the chamber;
   each motor is located outside of the chamber; and
   each motor is arranged to rotate a motor shaft of the substrate support movement apparatus.
24. A platform of a charged particle apparatus comprising the substrate movement arrangement according to clause 23.
25. A charged particle apparatus comprising:
   a platform according to any of clauses 1 to 6, wherein the platform comprises a substrate movement arrangement according to clause 23; and
   a charged particle beam generator.
26. A substrate support movement apparatus for moving a substrate support of a platform for a charged particle apparatus, the substrate support movement apparatus comprising:
   a first substrate drive arranged to move a substrate support in a first direction;
   a first motor arrangement arranged to move the first substrate drive;
   a first flexible damper arrangement arranged to support the first motor arrangement so that there is a passive balance mass arrangement for movements in the first direction;
   a second substrate drive arranged to move the substrate support in a second direction, wherein the second direction is orthogonal to the first direction;
   a second motor arrangement arranged to move the second substrate drive; and
   a second flexible damper arrangement arranged to support the second motor arrangement so that there is a passive balance mass arrangement for movements in the second direction.
27. The substrate support movement apparatus according to clause 26, wherein the first motor arrangement comprises:
   a first motor stator;
   a first motor element, connected to the first substrate drive, that is arranged to move relative to the first motor stator;
   a second motor stator; and
   a second motor element, connected to an opposite side of the first substrate drive than the first motor element, that is arranged to move relative to the second motor stator; and
   wherein:
   the first motor stator is arranged on a first flexible damper of the first flexible damper arrangement; and
   the second motor stator is arranged on a second flexible damper of the first flexible damper arrangement.
28. The substrate support movement apparatus according to clause 26 or 27, wherein the second motor arrangement comprises:
   a first motor stator;
   a first motor element, connected to the second substrate drive, that is arranged to move relative to the first motor stator;
   a second motor stator; and
   a second motor element, connected to an opposite side of the second substrate drive than the first motor element, that is arranged to move relative to the second motor stator; and
   wherein:
   the first motor stator is arranged on a first flexible damper of the second flexible damper arrangement; and
   the second motor stator is arranged on a second flexible damper of the second flexible damper arrangement.
29. The substrate support movement apparatus according to clause 27 or 28, further comprising one or more passive masses connected to one or more of the motor stators.
30. The substrate support movement apparatus according to any of clauses 27 to 29, wherein each motor stator comprises magnets.
31. The substrate support movement apparatus according to any of clauses 27 to 30, wherein each motor element comprises motor coils and/or a motor shaft.
32. The substrate support movement apparatus according to any of clauses 27 to 31, wherein the part of each motor element that is within a motor stator is orientated orthogonally to both the first direction and the second direction.
33. The substrate support movement apparatus according to any of clauses 26 to 32, wherein the first and second flexible damper arrangements are mounted on a substrate stage frame; and the substrate stage frame is mounted on a substrate stage interface frame so that the substrate stage frame is substantially isolated from a chamber of the platform for a charged particle apparatus.
34. The substrate support movement apparatus according to any of clauses 26 to 32, wherein the first and second flexible damper arrangements are mounted on a substrate stage frame; and the substrate stage frame is mounted on a chamber of the platform for a charged particle apparatus.
35. A platform of a charged particle apparatus comprising the substrate support movement apparatus according to any of clauses 26 to 34.
36. A charged particle apparatus comprising:
   a platform according to any of clauses 1 to 6, wherein the platform comprises a substrate support movement apparatus according to any of clauses 26 to 34; and
   a charged particle beam generator.
37. A platform for a charged particle apparatus, the platform comprising:
   a base frame;
   a top frame arranged above the base frame; and
   one or more frame connecting devices arranged to connect the top frame to the base frame;
   wherein each frame connecting device has a defined stiffness and damping such that the top frame is flexibly connected to the base frame.
38. The platform according to clause 37, wherein the stiffness and damping of the frame connecting devices are set so that a resonance between the top frame and the base frame occurs substantially at the same frequency as a resonance of the base frame.
39. The platform according to clause 37, wherein the stiffness and damping of the frame connecting devices are set so that a resonance between the top frame and the base frame occurs at a substantially lower frequency than the lowest resonant frequency of the base frame.
40. The platform according to any of clauses 37 to 39, wherein the top frame comprises one or more modules of the charged particle apparatus.
41. The platform according to clause 40, wherein each module is rigidly connected to the top frame.
42. The platform according to clauses 40, wherein each module is connected to the top frame and/or another module by one or more module connecting devices; and
   each module connecting device has a defined stiffness and damping such that each module is flexibly connected to the top frame and/or another module.
43. A platform for a charged particle apparatus, the platform comprising:
   a base frame; and
   a top frame arranged above the base frame;
   wherein:
   the top frame comprises one or more modules of the charged particle apparatus;
   each module is connected to the top frame and/or another module by one or more module connecting devices; and
   each module connecting device has a defined stiffness and damping such that each module is flexibly connected to the top frame and/or another module.
44. The platform according to clause 43, wherein the stiffness and damping of the one or more module connecting devices are set so that a resonance between the one or more modules and the top frame occurs substantially at the same frequency as a resonance of the base frame.
45. The platform according to clause 43, wherein the stiffness and damping of the one or more module connecting devices are set so that a resonance between the one or more modules and the top frame occurs at a substantially lower frequency than the lowest resonant frequency of the base frame.
46. The platform according to any of clauses 43 to 45, wherein the top frame is rigidly connected to the base frame.
47. The platform according to any of clauses 43 to 45, further comprising one or more frame connecting devices arranged to connect the top frame to the base frame;
   wherein each frame connecting device has a defined stiffness and damping such that the top frame is flexibly connected to the base frame.
48. A charged particle apparatus comprising:
   a platform according to any of clauses 37 to 47; and
   a charged particle beam generator.
49. A charged particle apparatus comprising:
   a platform according to any of clauses 1 to 6, wherein the platform is a platform according to any of clauses 37 to 47; and
   a charged particle beam generator.

While the present invention has been described in connection with various embodiments, other embodiments will be apparent to those skilled in the art from consideration of the specification and practice of the technology disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A platform for a charged particle apparatus, the platform comprising:
a base frame;
a chamber arranged to comprise a substrate;
a metrology frame arranged to support a charged particle beam generator for irradiating a substrate in the chamber with a charged particle beam; and
a bellow arranged between the metrology frame and the chamber;
wherein:
the chamber is rigidly connected to the base frame;
the bellow comprises a flexible material such that the metrology frame is substantially isolated from any vibrations that are generated in the chamber; and
the bellow is air tight so that a substantial vacuum may be established in the chamber.

2. The platform according to claim 1, further comprising air mounts arranged to support the metrology frame on the base frame.

3. The platform according to claim 1, further comprising a substrate support arrangement within the chamber;
wherein the substrate support arrangement is rigidly secured to the chamber.

4. The platform according to claim 3, wherein the substrate support arrangement comprises:
a long stroke arrangement that comprises one or more long stroke drives and a long stroke carrier; and
a short stroke arrangement that is arranged to support a substrate;
wherein:
the long stroke drives are arranged to move the long stroke carrier; and
the short stroke arrangement is flexibly supported by the long stroke carrier so that the short stroke arrangement is substantially isolated from vibrations that are generated by the long stroke arrangement.

5. The platform according to claim 4, wherein the long stroke carrier comprises one or more Lorenz motors that are arranged so that the short stroke arrangement floats above the long stroke carrier.

6. The platform according to claim 1, further comprising one or more pumps for establishing a substantial vacuum in the chamber;
wherein the one or more pumps are directly connected to the base frame.

7. A charged particle apparatus comprising:
the platform of claim 1; and
a charged particle beam generator.

8. The charged particle apparatus according to claim 7, wherein the charged particle beam generator is arranged to emit a multi-beam of charged particles.

9. A bellow for proving a connection between a vacuum chamber and a metrology frame in a platform for a charged particle apparatus, the bellow comprising:
a layer of material arranged in a loop;
wherein:
the material is flexible and substantially air tight;
the layer comprises a first end for securing to the chamber; and
the layer comprises a second end for securing to the metrology frame.

10. The bellow according to claim 9, wherein the layer is a first layer, and the bellow further comprises:
a second layer of material arranged in a loop; and
an outflow conduit;
wherein:
the second layer is separated from the first layer so that there is an enclosed region between the first layer and second layer;
the outflow conduit is arranged to extract gas from the enclosed region;
the material of the second layer is flexible and substantially air tight;
the second layer comprises a first end for securing to the chamber; and
the second layer comprises a second end for securing to the metrology frame.

11. The bellow according to claim 10, wherein the enclosed region is a first enclosed region, the bellow further comprising:
a third layer of material arranged in a loop; and
an inflow conduit;
wherein:
the third layer is separated from the first layer and on an opposite side of the first layer to the second layer so that there is a second enclosed region between the first layer and second layer;
the inflow conduit is arranged to provide a gas flow into the second enclosed region;
the material of the third layer is flexible and substantially air tight;
the third layer comprises a first end for securing to the chamber; and
the third layer comprises a second end for securing to the metrology frame.

12. The bellow according to claim 11, wherein:
the inflow conduit is arranged to pressurise the second enclosed region to a higher pressure than the ambient pressure around the platform;
the outflow conduit is arranged to extract gas from the first enclosed region so that the first enclosed region is at a substantially lower pressure than the second enclosed region.

13. The bellow according to claim 9, wherein the material of the first, second, and/or third layer is rubber.

14. A platform for a charged particle apparatus comprising:
a chamber;
a metrology frame; and
a bellow according to claim 9;
wherein:
an inner side of the bellow is arranged to support a substantial vacuum in the chamber; and
an outer side of the bellow is arranged to withstand the ambient pressure around the platform.

15. A charged particle apparatus comprising:
a charged particle beam generator; and
a platform comprising:
a base frame;
a chamber arranged to comprise a substrate, wherein the chamber is rigidly connected to the base frame;
a metrology frame arranged to support the charged particle beam generator for irradiating a substrate in the chamber with a charged particle beam; and
a bellow arranged between the metrology frame and the chamber, the bellow comprising:
a layer of material arranged in a loop;
wherein:
the material is substantially air tight such that the metrology frame is substantially isolated from any vibrations that are generated in the chamber,
the material is flexible such that the metrology frame is substantially isolated from any vibrations that are generated in the chamber;
the layer comprises a first end for securing to the chamber; and
the layer comprises a second end for securing to the metrology frame.
